(19) United States
(12) Patent Application Publication
(10) Pub. No.: US 2025/0244685 A1
(43) Pub. Date: Jul. 31, 2025

(54) PHOTO-PATTERNABLE LATENT-CHEMISTRY INORGANIC MATERIALS

(71) Applicant: Meta Platforms Technologies, LLC, Menlo Park, CA (US)

(72) Inventors: Alejo LIFSCHITZ ARRIBIO, Redmond, WA (US); Anthony PHAN, Redmond, WA (US)

(21) Appl. No.: 18/630,544

(22) Filed: Apr. 9, 2024

Related U.S. Application Data
(60) Provisional application No. 63/459,340, filed on Apr. 14, 2023.

(51) Int. Cl. G03F 7/00; G03F 7/004

(52) U.S. Cl. CPC G03F 7/70958; G03F 7/0043; G03F 7/0045; G03F 7/70408

(57) ABSTRACT

Techniques disclosed herein relate to photo-patternable latent-chemistry inorganic materials. An example of the photo-patternable latent-chemistry inorganic materials includes a sol-gel material comprising a solution containing a tin dichloride salt, a solvent including at least one alcohol-containing solvent, and optionally a photo-acid generator or photo-acid. The sol-gel material, upon selective photo-excitation (which forms a latent pattern with latent chemistry in the sol-gel material) and blanket thermal annealing, can form a coating having a formula SnO(n)X(m), where the n:m ratio and n-m values of the coating vary across regions of the coating, such that a refractive index of the coating varies across regions of the coating, without affecting the coating's transparency for visible light.

### CROSS-REFERENCE TO RELATED APPLICATIONS

This application claims the benefit of and priority to U.S. Provisional Application No. 63/459,340, filed Apr. 14, 2023, entitled “PHOTO-PATTERNABLE LATENT-CHEMISTRY INORGANIC MATERIALS,” which is incorporated herein by reference in its entirety.

### BACKGROUND

An artificial reality system, such as a head-mounted display (HMD) or heads-up display (HUD) system, generally includes a near-eye display system in the form of a headset or a pair of glasses and configured to present content to a user via an electronic or optic display within, for example, about 10-20 mm in front of the user's eyes. The near-eye display system may display virtual objects or combine images of real objects with virtual objects, as in virtual reality (VR), augmented reality (AR), or mixed reality (MR) applications. For example, in an AR system, a user may view both images of virtual objects (e.g., computer-generated images (CGIs)) and the surrounding environment by, for example, seeing through transparent display glasses or lenses (often referred to as optical see-through).

One example of an optical see-through AR system may use a waveguide-based optical display, where light of projected images may be coupled into a waveguide (e.g., a transparent substrate), propagate within the waveguide, and be coupled out of the waveguide at different locations. In some implementations, the light of the projected images may be coupled into or out of the waveguide using a diffractive optical element, such as a holographic grating. In some implementations, the artificial reality systems may employ eye-tracking subsystems that can track the user's eye (e.g., gaze direction) to modify or generate content based on the direction in which the user is looking, thereby providing a more immersive experience for the user. The eye-tracking subsystems may be implemented using various optical components, such as holographic optical elements.

Sol-gels are materials composed of a solution comprising a metal oxide precursor that may have been partially or fully condensed into an extended network. Upon coating the solution and annealing of the sol-gel, the precursor ligands and solvent may be removed to fully condense the extended network into an oxide or inorganic film. The condensation process may result in densification and, potentially, crystallization. Thus, when applied onto a substrate and annealed, sol-gels can be used to manufacture transparent, high refractive-index (RI) coatings.

### SUMMARY

This disclosure relates generally to sol-gel materials for fabricating holographic optical elements, where a refractive index (RI) of the sol-gel material may be modulated by photo-excitation and thermal annealing. New materials and processing conditions based on tin (Sn) and photo-acid generator photochemistry are disclosed herein. More specifically, techniques disclosed herein relate to photo-patternable, latent-chemistry activated inorganic sol-gel materials including SnO(m)Cl(n). The sol-gel materials may be transparent and may stay in an amorphous state without any noticeable domain formation. The sol-gel materials disclosed herein may achieve highly condensed states with RI values in a range of about 1.6-2.35, depending on the m-n values and the m:n ratio. The RI of the SnO(m)Cl(n) optical coating may depend on the chemical environment around the tin (Sn) centers prior to the thermal anneal, which may reduce the thickness of the optical coating. Upon photo-exposure, the RI of the optical coating may change substantially as a result of relevant chemical changes around Sn centers. In various embodiments, photochemistry of the Sn may trigger the RI change. In other instances, Sn may be used in conjunction with photo-acid generators. Variation in RI may be up to about 0.74. In various embodiments, the thickness difference may be less than 5%, and the variation in RI may be about 0.35. Various inventive embodiments are described herein, including devices, systems, methods, materials, processes, compositions, and the like.

According to certain embodiments, a sol-gel material for recording holographic optical elements (e.g., volume Bragg gratings) may include a (precursor) solution containing a tin dichloride salt, at least one alcohol-containing solvent, and optionally a photo-acid generator or photo-acid. The sol-gel material may be used to form a continuous coating characterized by a formula SnO(n)X(m) as a result of selective photo-excitation followed by blanket thermal annealing, where the n-m ratio and n-m values may vary across regions of the coating, such that the local RI of the coating is actively varied without affecting the coating's transparency.

In some embodiments, the tin dichloride salt may include anhydrous tin dichloride, tin dichloride hydrate, or tin (II) ions and chloride ions provided to the solution from separate salts. The solvent may contain at least one alcohol, such as an alkyl alcohol, a glycol, or a diol. The solvent may be a solvent mixture that may include at least one of dipropylene Glycol Monomethyl Ether (DPGME), propylene Glycol Monomethyl Ether (PGME), ethanol, isopropanol, propanol, 1,3-Dimethoxy-2-propanol, and diethylene glycol, propylene glycol methyl ether acetate, tripropylene glycol monomethyl ether, butyl lactate, propylene carbonate, methanol, or water. The coating solution may optionally include a photo-acid generator or photo-acid. The photo-acid generator or photo-acid may include at least one of a diarylsulfonium compound, a diazomethane compound, a bis (sulfonyl) diazomethane compound, a Diaryliodonium compound, a triarylselenonium compound, an arene ferrocene compound, or a sulfonic acid ester compound.

In some embodiments, a coating may be prepared from the sol-gel precursor solution to form a layer composed of SnO(n)X(m). The coating, once thermally annealed and optionally photo-cured, may have an RI between about 1.65 and about 2.35, where all portions of the coating may show absorption values less than about 0.1% in the visible spectrum. In some embodiments, a coating composed of SnO(n)X(m) with variable n-m values and n:m ratio may be resulted from selective photo-curing of the coating prior to completing the thermal annealing process, such that local RI values may vary from about 1.65 to about 2.35 and all portions of the film may show absorption values less than about 0.1% in the visible spectrum. In some embodiments, a coating may include photo-exposed regions having RI values that are lower than those of the non-photo-exposed regions, and the photo-exposed regions may have an n value of about 1.5-2 and an m:n ratio greater than about 3. In some embodiments, the m-n values, men ratio, and resultant local RI values of a coating disclosed herein may be controlled by the intensity, exposure time, and wavelength of photo-excitation followed by thermal annealing.

In some embodiments, a process may include applying the sol-gel precursor solution disclosed herein onto a substrate via spin-coating, ink-jet printing, dip-coating, spray-coating, screen-printing, contact-printing, or casting, to form a coating layer. In some embodiments, a portion of the coating layer may be cured using a light source with an excitation wavelength longer than about 365 nm and excitation power no more than about 300 mW/cm² for about 0.001 to about 300 seconds, such that the photo-exposed areas may have a lower RI value than the non-exposed areas after thermal annealing. In some embodiments, a portion of the coating layer may be photo-cured using a light pattern formed by constructive and destructive interference to create a (latent) holographic optical element (e.g., VBG) within the coating following thermal annealing. The substrate with the photo-cured coating layer may be thermally annealed via at least 1 stage of thermal annealing after photo-excitation, at annealing temperatures lower than about 300° C., or may optionally be thermally annealed via at least 2 stages of annealing, where the initial anneal may occur before or after the photo-excitation step, the temperature of the first anneal step is lower than about 200° C., and the temperature of the final anneal step is lower than about 300° C. After the thermal annealing, a transparent coating with local variations in RI may be formed, where the local RI may vary by at least about 0.1 (refractive index modulation) and the overall RI may vary in the range of about 1.65-2.35.

This summary is neither intended to identify key or essential features of the claimed subject matter, nor is it intended to be used in isolation to determine the scope of the claimed subject matter. The subject matter should be understood by reference to appropriate portions of the entire specification of this disclosure, any or all drawings, and each claim. The foregoing, together with other features and examples, will be described in more detail below in the following specification, claims, and accompanying drawings.

### BRIEF DESCRIPTION OF THE DRAWINGS

Illustrative embodiments are described in detail below with reference to the following figures.

FIG. 1 is a simplified block diagram of an example of an artificial reality system environment including a near-eye display system according to certain embodiments.

FIG. 2 is a perspective view of an example of a near-eye display system in the form of a head-mounted display (HMD) device for implementing some of the examples disclosed herein.

FIG. 3 is a perspective view of an example of a near-eye display system in the form of a pair of glasses for implementing some of the examples disclosed herein.

FIG. 4 illustrates an example of an optical see-through augmented reality system using a waveguide display that includes an optical combiner according to certain embodiments.

FIG. 5A illustrates an example of a volume Bragg grating (VBG).

FIG. 5B illustrates the Bragg condition for the volume Bragg grating shown in FIG. 5A.

FIG. 6 illustrates an example of a holographic recording material including two-stage photopolymers.

FIG. 7A illustrates the recording light beams for recording a volume Bragg grating and the light beam reconstructed from the volume Bragg grating.

FIG. 7B is an example of a holography momentum diagram illustrating the wave vectors of recording beams and reconstruction beams and the grating vector of the recorded volume Bragg grating.

FIG. 8 illustrates an example of a holographic recording system for recording holographic optical elements.

FIGS. 9A-9D illustrate an example of free radical polymerization in an example of a photopolymer material. FIG. 9A illustrates the photopolymer material before polymerization. FIG. 9B illustrates the initiation of monomer chains. FIG. 9C illustrates the propagation of the monomer chains. FIG. 9D illustrates the termination of the monomer chains.

FIGS. 10A-10C illustrate an example of recording a holographic optical element in an uncontrolled photopolymer material layer. FIG. 10A illustrates the unexposed photopolymer material layer. FIG. 10B illustrates monomer diffusion and polymerization during the holographic recording. FIG. 10C illustrates an example of polymer diffusion after the exposure.

FIG. 11 illustrates an example of a process of generating refractive index modulation in an optical film.

FIG. 12 illustrates an example of a process of recording a pattern in a photo-reactive inorganic film.

FIGS. 13A-13D illustrate examples of materials that can be utilized to record holographic optical elements or holographic patterns.

FIG. 14 illustrates an example of displacing labile ligands in a sol-gel coating with photo-generated base for refractive index modulation.

FIGS. 15-23 illustrate examples of experimental results using comparative materials and processes, and materials and processes disclosed herein according to certain embodiments.

FIG. 24 is a simplified block diagram of an example of an electronic system of a near-eye display system (e.g., HMD device) for implementing some of the examples disclosed herein according to certain embodiments.

The figures depict embodiments of the present disclosure for purposes of illustration only. One skilled in the art will readily recognize from the following description that alternative embodiments of the structures and methods illustrated may be employed without departing from the principles, or benefits touted, of this disclosure.

In the appended figures, similar components and/or features may have the same reference label. Further, various components of the same type may be distinguished by following the reference label by a dash and a second label that distinguishes among the similar components. If only the first reference label is used in the specification, the description is applicable to any one of the similar components having the same first reference label irrespective of the second reference label.

### DETAILED DESCRIPTION

Techniques disclosed herein relate generally to sol-gel materials for fabricating holographic optical elements, where the refractive index (RI) of the sol-gel material may be modulated by photo-excitation and thermal annealing. Various new materials and processing conditions based on tin (Sn) and photo-acid generator photochemistry are disclosed herein. More specifically, techniques disclosed herein relate to photo-patternable, latent-chemistry activated inorganic sol-gel materials including SnO(m)Cl(n). The sol-gel materials may be transparent and may stay in an amorphous state without any noticeable domain formation. The sol-gel materials disclosed herein may achieve highly condensed states with RI values in a range of about 1.6-2.35, depending on the m-n values and the men ratio. The RI of the SnO(m)Cl(n) optical coating may depend on the chemical environment around the tin (Sn) centers prior to the thermal anneal, which may reduce the thickness of the optical coating. Upon photo-exposure, the RI of the optical coating may change substantially as a result of relevant chemical changes around Sn centers. In various embodiments, photochemistry of the Sn may trigger the RI change. In other instances, Sn may be used in conjunction with photo-acid generators. Variation in RI may be up to about 0.74. In various embodiments, thickness difference may be less than about 5%, and variation in RI may be about 0.35. Various inventive embodiments are described herein, including devices, systems, methods, materials, processes, compositions, and the like.

In various optical systems, such as artificial reality systems including virtual reality, augmented reality (AR), and mixed reality (MR) systems, to improve the performance of the optical systems, such as improving the brightness of the displayed images, expanding the eyebox, reducing artifacts, increasing the field of view, and improving user interaction with presented content, various holographic optical elements may be used for light beam coupling and shaping, such as coupling light into or out of a waveguide display or tracking the motion of the user's eyes. These holographic optical elements may need to have a high refractive index modulation, a small pitch or feature size, high clarity, high diffraction efficiency, and the like.

Photo-reactive materials that can have a local change in refractive index (RI) upon light excitation can be used to record Volume Bragg Gratings (VBG), holographic pattern, or create RI gradients in an optical film or coating. These materials can thus be used as waveguide (WG) components in VR/AR/MR devices, wherein the photo-generated pattern controls the refraction and diffraction efficiency of light as it travels through the coating. In order to increase the efficiency of the WG device, the WG device may need to have certain characteristics.

For example, it may be desirable that the WG device has a large RI contrast or RI modulation (Δn) between photo-exposed areas and unexposed areas (e.g., Δn>0.05). This is because the higher the Δn, the higher the diffraction efficiency of the WG device may achieve.

Both photo-exposed and unexposed areas need to be transparent to visible light after the material is fully processed (e.g., with absorption <0.1%/100 nm) because, for the coating to allow total internal reflection (TIR) with minimal absorption losses, the material should not be capable of electronic absorption of the light traveling through it. Otherwise, if either the photo-exposed or unexposed areas can absorb visible light, the efficiency of the WG display will be lowered. The thickness difference between photo-exposed and unexposed areas needs to be minimized to prevent surface scattering and diffraction (e.g., <20% of total coating thickness). More specifically, variations in coating thickness along the length of the WG may lead to optical artifacts, such as ghost images, or decreased image quality, such as pupil swim. Furthermore, periodic variation in the coating thickness, such as distinct thickness changes in the exposed regions, may act as surface relief gratings having their own diffractive behavior and thus disrupting the functionality of the overall WG display system.

In addition, the photo-exposure should lead to a pattern of chemical or thermal reactivity that only produces a distinct change in RI index after the material undergoes post-processing. This behavior is referred to as photo-induced latent chemistry, where the photo-exposure process itself does not lead to a significant change in RI. Instead, it leaves behind a pattern of reactivity that is exploited in a subsequent step, such as thermal annealing. This latent chemistry behavior is particularly important when undergoing photo-exposure via light patterns formed by constructive and destructive interference or when it is critical to achieve nm-scale resolution between photo-exposed and unexposed areas. The reason is that the generation of a local An can itself diffract the light that is used to photo-pattern the material, thereby leading to parasitic grating formation or other aberrations in the diffraction and refraction behavior of the pattern. By de-coupling photo-excitation from An formation into two separate processing steps (photo-excitation and post-processing), the photo-reactive material can be exposed for as long as needed, without compromising the An pattern quality.

Furthermore, photo-excitation or post-processing should not entail the long-range (e.g., >10 nm) reorganization of components within the material, so as to prevent potential scattering issues. That is, if photo-exposure or post-processing result in displacement of a given component, such as a particle or a growing organic polymer chain, there will be a significant risk that the components agglomerate into units that are larger than 1/10 of the wavelength of light. As a result, the agglomerates may scatter light as the light travels through the optical coating, and the image quality of the WG display will be severely impacted.

Therefore, there is a need for materials that can be incorporated into WG devices as optical coatings, and can react to photo-excitation by creating a pattern of latent chemistry that leads to a large Δn upon post-processing. These materials should be fully transparent in both photo-exposed and nonexposed areas once post-processing is completed, and they should result in minimal thickness variations within all areas of the coating.

According to certain embodiments, a sol-gel material for recording holographic optical elements (e.g., volume Bragg gratings) may include a (precursor) solution containing a tin dichloride salt, at least one alcohol-containing solvent, and optionally a photo-acid generator or photo-acid. The sol-gel material may be used to form a continuous coating characterized by a formula SnO(n)X(m) as a result of selective photo-excitation followed by blanket thermal annealing, where the n-m ratio and n-m values may vary across regions of the coating, such that the local RI of the coating is actively varied without affecting the coating's transparency.

In some embodiments, the tin dichloride salt may include anhydrous tin dichloride, tin dichloride hydrate, or tin (II) ions and chloride ions provided to the solution from separate salts. The solvent may contain at least one alcohol, such as an alkyl alcohol, a glycol, or a diol. The solvent may be a solvent mixture that may include at least one of dipropylene Glycol Monomethyl Ether (DPGME), propylene Glycol Monomethyl Ether (PGME), ethanol, isopropanol, propanol, 1,3-Dimethoxy-2-propanol, and diethylene glycol, propylene glycol methyl ether acetate, tripropylene glycol monomethyl ether, butyl lactate, propylene carbonate, methanol, or water. The coating solution may optionally include a photo-acid generator or photo-acid. The photo-acid generator or photo-acid may include at least one of a diarylsulfonium compound, a diazomethane compound, a bis (sulfonyl) diazomethane compound, a Diaryliodonium compound, a triarylselenonium compound, an arene ferrocene compound, or a sulfonic acid ester compound.

In some embodiments, a coating may be prepared from the sol-gel precursor solution to form a layer composed of SnO(n)X(m). The coating, once thermally annealed and optionally photo-cured, may have an RI between about 1.65 and about 2.35, where all portions of the coating may show absorption values less than about 0.1% in the visible spectrum. In some embodiments, a coating composed of SnO(n)X(m) with variable n-m values and n:m ratio may be resulted from selective photo-curing of the coating prior to completing the thermal annealing process, such that local RI values may vary from about 1.65 to about 2.35 and all portions of the film may show absorption values less than about 0.1% in the visible spectrum. In some embodiments, a coating may include photo-exposed regions having RI values that are lower than those of the non-photo-exposed regions, and the photo-exposed regions may have an n value of about 1.5-2 and an men ratio greater than about 3. In some embodiments, the m-n values, men ratio, and resultant local RI values of a coating disclosed herein may be controlled by the intensity, exposure time, and wavelength of photo-excitation followed by thermal annealing.

In some embodiments, a process may include applying the sol-gel precursor solution disclosed herein onto a substrate via spin-coating, ink-jet printing, dip-coating, spray-coating, screen-printing, contact-printing, or casting, to form a coating layer. In some embodiments, a portion of the coating layer may be cured using a light source with an excitation wavelength longer than about 365 nm and excitation power no more than about 300 mW/cm² for about 0.001 to about 300 seconds, such that the photo-exposed areas may have a lower RI value than the non-exposed areas after thermal annealing. In some embodiments, a portion of the coating layer may be photo-cured using a light pattern formed by constructive and destructive interference to create a (latent) holographic optical element (e.g., VBG) within the coating following thermal annealing. The substrate with the photo-cured coating layer may be thermally annealed via at least 1 stage of thermal annealing after photo-excitation, at annealing temperatures lower than about 300° C., or may optionally be thermally annealed via at least 2 stages of annealing, where the initial anneal may occur before or after the photo-excitation step, the temperature of the first anneal step is lower than about 200° C., and the temperature of the final anneal step is lower than about 300° C. After the thermal annealing, a transparent coating with local variations in RI may be formed, where the local RI may vary by at least about 0.1 (refractive index modulation) and the overall RI may vary in the range of about 1.65-2.35.

As used herein, visible light may refer to light with a wavelength between about 380nm and about 750 nm, between about 400 nm and about 700 nm, or between about 440 nm and about 650 nm. Near infrared (NIR) light may refer to light with a wavelength between about 750 nm to about 2500 nm. The desired infrared (IR) wavelength range may refer to the wavelength range of IR light that can be detected by a suitable IR sensor (e.g., a complementary metal-oxide semiconductor (CMOS), a charge-coupled device (CCD) sensor, or an InGaAs sensor), such as between 830 nm and 860 nm, between 930 nm and 980 nm, or between about 750 nm to about 1000 nm.

As also used herein, a substrate may refer to a medium within which light may propagate. The substrate may include one or more types of dielectric materials, such as glass, quartz, plastic, polymer, poly (methyl methacrylate) (PMMA), crystal, or ceramic. At least one type of material of the substrate may be transparent to visible light and NIR light. A thickness of the substrate may range from, for example, less than about 1 mm to about 10 mm or more. As used herein, a material may be “transparent” to a light beam if the light beam can pass through the material with a high transmission rate, such as larger than 60%, 75%, 80%, 90%, 95%, 98%, 99%, or higher, where a small portion of the light beam (e.g., less than 40%, 25%, 20%, 10%, 5%, 2%, 1%, or less) may be scattered, reflected, or absorbed by the material. The transmission rate (i.e., transmissivity) may be represented by either a photopically weighted or an unweighted average transmission rate over a range of wavelengths, or the lowest transmission rate over a range of wavelengths, such as the visible wavelength range.

As also used herein, the term “support matrix” refers to the material, medium, substance, etc., in which the polymerizable component is dissolved, dispersed, embedded, enclosed, etc. In some embodiments, the support matrix is typically a low Te polymer. The polymer may be organic, inorganic, or a mixture of the two. Without being particularly limited, the polymer may be a thermoset or thermoplastic.

As also used herein, the term “free radical polymerization” refers to any polymerization reaction that is initiated by any molecule comprising a free radical or radicals.

As also used herein, the term “cationic polymerization” refers to any polymerization reaction that is initiated by any molecule comprising a cationic moiety or moieties.

As also used herein, the term “anionic polymerization” refers to any polymerization reaction that is initiated by any molecule comprising an anionic moiety or moieties.

As also used herein, the term “photoinitiator” refers to the conventional meaning of the term photoinitiator and also refers to sensitizers and dyes. In general, a photoinitiator causes the light initiated polymerization of a material, such as a photoactive oligomer or monomer, when the material containing the photoinitiator is exposed to light of a wavelength that activates the photoinitiator, e.g., a photoinitiating light source. The photoinitiator may refer to a combination of components, some of which individually are not light sensitive, yet in combination are capable of curing the photoactive oligomer or monomer, examples of which include a dye/amine, a sensitizer/iodonium salt, a dye/borate salt, and the like.

As also used herein, the term “polymerizable component” refers to one or more photoactive polymerizable materials, and optionally one or more additional polymerizable materials, e.g., monomers and/or oligomers, that are capable of forming a polymer.

As also used herein, the term “photoactive polymerizable material” refers to a monomer, an oligomer and combinations thereof that polymerize in the presence of a photoinitiator that has been activated by being exposed to a photoinitiating light source, e.g., recording light. In reference to the functional group that undergoes curing, the photoactive polymerizable material comprises at least one such functional group. It is also understood that there exist photoactive polymerizable materials that are also photoinitiators, such as N-methylmaleimide, derivatized acetophenones, etc., and that in such a case, it is understood that the photoactive monomer and/or oligomer of the present disclosure may also be a photoinitiator.

As also used herein, the term “photopolymer” refers to a polymer formed by one or more photoactive polymerizable materials, and optionally one or more additional monomers and/or oligomers.

As also used hercin, the term “polymerization inhibitor” refers to one or more compositions, compounds, molecules, etc., that are capable of inhibiting or substantially inhibiting the polymerization of the polymerizable component when the photoinitiating light source is on or off. Polymerization inhibitors typically react very quickly with radicals and effectively stop a polymerization reaction. Inhibitors cause an inhibition time during which little to no photopolymer forms, e.g., only very small chains. Typically, photopolymerization occurs only after nearly 100% of the inhibitor is reacted.

As also used herein, the term “chain transfer agent” refers to one or more compositions, compounds, molecules, etc. that are capable of interrupting the growth of a polymeric molecular chain by formation of a new radical that may react as a new nucleus for forming a new polymeric molecular chain. Typically, chain transfer agents cause the formation of a higher proportion of shorter polymer chains, relative to polymerization reactions that occur in the absence of chain transfer agents. In some embodiments, certain chain transfer agents can behave as retarders or inhibitors if they do not efficiently reinitiate polymerization.

As also used herein, the terms “photo-acid generators,” “photo-base generators,” and “photogenerated radicals,” refer to one or more compositions, compounds, molecules, etc., that, when exposed to a light source, generate one or more compositions, compounds, molecules, etc., that are acidic, basic, or a free radical.

As also used herein, the term “alkyl” refers to a straight or branched hydrocarbon chain radical consisting solely of carbon and hydrogen atoms, containing no unsaturation, having from one to ten carbon atoms (e.g., (C₁₋₁₀) alkyl or C₁₋₁₀ alkyl). Whenever it appears herein, a numerical range such as “1 to 10” refers to each integer in the given range—e.g., “1 to 10 carbon atoms” means that the alkyl group may consist of 1 carbon atom, 2 carbon atoms, 3 carbon atoms, etc., up to and including 10 carbon atoms, although the definition is also intended to cover the occurrence of the term “alkyl” where no numerical range is specifically designated. Typical alkyl groups include, but are in no way limited to, methyl, ethyl, propyl, isopropyl, n-butyl, isobutyl, sec-butyl isobutyl, tertiary butyl, pentyl, isopentyl, neopentyl, hexyl, septyl, octyl, nonyl and decyl. The alkyl moiety may be attached to the rest of the molecule by a single bond, such as for example, methyl (Me), ethyl (Et), n-propyl (Pr), 1-methylethyl (isopropyl), n-butyl, n-pentyl, 1,1-dimethylethyl (1-butyl) and 3-methylhexyl. Unless stated otherwise specifically in the specification, an alkyl group is optionally substituted by one or more of substituents which are independently heteroalkyl, alkenyl, alkynyl, cycloalkyl, heterocycloalkyl, aryl, arylalkyl, heteroaryl, heteroarylalkyl, hydroxy, halo, cyano, trifluoromethyl, trifluoromethoxy, nitro, trimethylsilanyl, —OR^{a}, —SR^{a}, —OC(O)—R^{a}, —N(R^{a})₂, —C(O)R^{a}, —C(O)OR^{a}, —OC(O)N(R^{a})₂, —C(O)N(R^{a})₂, —N(R^{a})C(O)OR^{a}, —N(R^{a})C(O)R^{a}, —N(R^{a})C(O)N(R^{a})₂, N(R^{a})C(NR^{a})N(R^{a})₂, —N(R^{a})S(O), R^{a} (where t is 1 or 2), —S(O), OR^{a} (where t is 1 or 2), —S(O), N(R^{a})₂ (where t is 1 or 2), —S(O), N(R^{a})C(O)R^{a} (where t is 1 or 2), or PO₃(R^{a})₂ where each R^{a} is independently hydrogen, fluoroalkyl, carbocyclyl, carbocyclylalkyl, aryl, aralkyl, heterocycloalkyl, heterocycloalkylalkyl, heteroaryl or heteroarylalkyl.

In the following description, for the purposes of explanation, specific details are set forth in order to provide a thorough understanding of examples of the disclosure. However, it will be apparent that various examples may be practiced without these specific details. For example, devices, systems, structures, assemblies, methods, and other components may be shown as components in block diagram form in order not to obscure the examples in unnecessary detail. In other instances, well-known devices, processes, systems, structures, and techniques may be shown without necessary detail in order to avoid obscuring the examples. The figures and description are not intended to be restrictive. The terms and expressions that have been employed in this disclosure are used as terms of description and not of limitation, and there is no intention in the use of such terms and expressions of excluding any equivalents of the features shown and described or portions thereof. The word “example” is used herein to mean “serving as an example, instance, or illustration.” Any embodiment or design described herein as “example” is not necessarily to be construed as preferred or advantageous over other embodiments or designs.

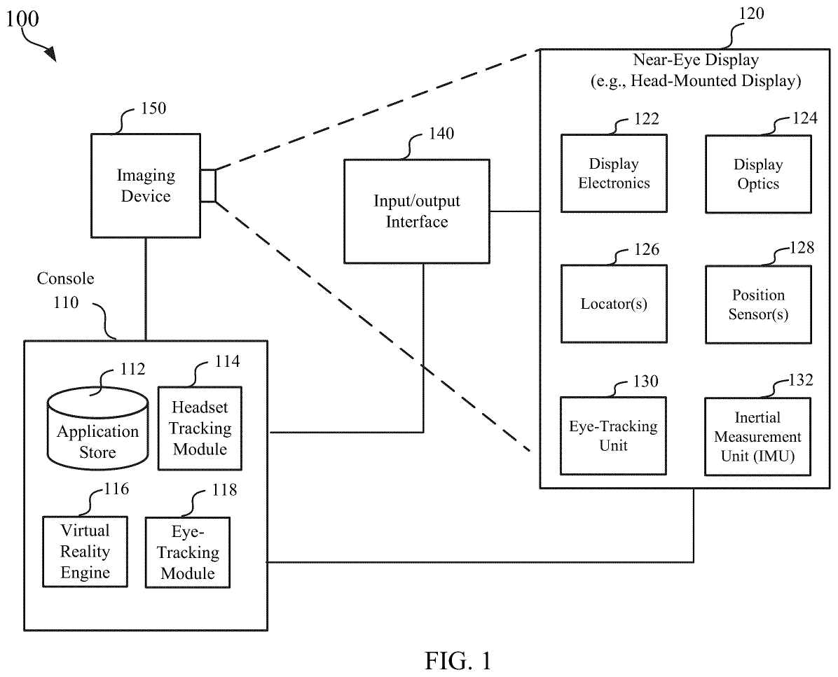

FIG. 1 is a simplified block diagram of an example of an artificial reality system environment 100 including a near-eye display system 120 in accordance with certain embodiments. Artificial reality system environment 100 shown in FIG. 1 may include near-eye display system 120, an optional imaging device 150, and an optional input/output interface 140 that may each be coupled to an optional console 110. While FIG. 1 shows example artificial reality system environment 100 including one near-eye display system 120, one imaging device 150, and one input/output interface 140, any number of these components may be included in artificial reality system environment 100, or any of the components may be omitted. For example, there may be multiple near-eye display systems 120 monitored by one or more external imaging devices 150 in communication with console 110. In some configurations, artificial reality system environment 100 may not include imaging device 150, optional input/output interface 140, and optional console 110. In alternative configurations, different or additional components may be included in artificial reality system environment 100. In some configurations, near-eye display systems 120 may include imaging device 150, which may be used to track one or more input/output devices (e.g., input/output interface 140), such as a handhold controller.

Near-eye display system 120 may be a head-mounted display that presents content to a user. Examples of content presented by near-eye display system 120 include one or more of images, videos, audios, or some combination thereof. In some embodiments, audios may be presented via an external device (e.g., speakers and/or headphones) that receives audio information from near-eye display system 120, console 110, or both, and presents audio data based on the audio information. Near-eye display system 120 may include one or more rigid bodies, which may be rigidly or non-rigidly coupled to each other. A rigid coupling between rigid bodies may cause the coupled rigid bodies to act as a single rigid entity. A non-rigid coupling between rigid bodies may allow the rigid bodies to move relative to each other. In various embodiments, near-eye display system 120 may be implemented in any suitable form factor, including a pair of glasses. Some embodiments of near-eye display system 120 are further described below. Additionally, in various embodiments, the functionality described herein may be used in a headset that combines images of an environment external to near-eye display system 120 and artificial reality content (e.g., computer-generated images). Therefore, near-eye display system 120 may augment images of a physical, real-world environment external to near-eye display system 120 with generated content (e.g., images, video, sound, etc.) to present an augmented reality to a user.

In various embodiments, near-eye display system 120 may include one or more of display electronics 122, display optics 124, and an eye-tracking system 130. In some embodiments, near-eye display system 120 may also include one or more locators 126, one or more position sensors 128, and an inertial measurement unit (IMU) 132. Near-eye display system 120 may omit any of these elements or include additional elements in various embodiments. Additionally, in some embodiments, near-eye display system 120 may include elements combining the function of various elements described in conjunction with FIG. 1.

Display electronics 122 may display or facilitate the display of images to the user according to data received from, for example, console 110. In various embodiments, display electronics 122 may include one or more display panels, such as a liquid crystal display (LCD), an organic light emitting diode (OLED) display, an inorganic light emitting diode (ILED) display, a micro light emitting diode (μLED) display, an active-matrix OLED display (AMOLED), a transparent OLED display (TOLED), or some other display. For example, in one implementation of near-eye display system 120, display electronics 122 may include a front TOLED panel, a rear display panel, and an optical component (e.g., an attenuator, polarizer, or diffractive or spectral film) between the front and rear display panels. Display electronics 122 may include pixels to emit light of a predominant color such as red, green, blue, white, or yellow. In some implementations, display electronics 122 may display a three-dimensional (3D) image through stereo effects produced by two-dimensional panels to create a subjective perception of image depth. For example, display electronics 122 may include a left display and a right display positioned in front of a user's left eye and right eye, respectively. The left and right displays may present copies of an image shifted horizontally relative to each other to create a stereoscopic effect (i.e., a perception of image depth by a user viewing the image).

In certain embodiments, display optics 124 may display image content optically (e.g., using optical waveguides and couplers), magnify image light received from display electronics 122, correct optical errors associated with the image light, and present the corrected image light to a user of near-eye display system 120. In various embodiments, display optics 124 may include one or more optical elements, such as, for example, a substrate, optical waveguides, an aperture, a Fresnel lens, a convex lens, a concave lens, a filter, input/output couplers, or any other suitable optical elements that may affect image light emitted from display electronics 122. Display optics 124 may include a combination of different optical elements as well as mechanical couplings to maintain relative spacing and orientation of the optical elements in the combination. One or more optical elements in display optics 124 may have an optical coating, such as an anti-reflective coating, a reflective coating, a filtering coating, or a combination of different optical coatings.

Magnification of the image light by display optics 124 may allow display electronics 122 to be physically smaller, weigh less, and consume less power than larger displays. Additionally, magnification may increase a field of view of the displayed content. The amount of magnification of image light by display optics 124 may be changed by adjusting, adding, or removing optical elements from display optics 124. In some embodiments, display optics 124 may project displayed images to one or more image planes that may be further away from the user's eyes than near-eye display system 120/

Display optics 124 may also be designed to correct one or more types of optical errors, such as two-dimensional optical errors, three-dimensional optical errors, or a combination thereof. Two-dimensional errors may include optical aberrations that occur in two dimensions. Example types of two-dimensional errors may include barrel distortion, pincushion distortion, longitudinal chromatic aberration, and transverse chromatic aberration. Three-dimensional errors may include optical errors that occur in three dimensions. Example types of three-dimensional errors may include spherical aberration, comatic aberration, field curvature, and astigmatism.

Locators 126 may be objects located in specific positions on near-eye display system 120 relative to one another and relative to a reference point on near-eye display system 120. In some implementations, console 110 may identify locators 126 in images captured by imaging device 150 to determine the artificial reality headset's position, orientation, or both. A locator 126 may be a light emitting diode (LED), a corner cube reflector, a reflective marker, a type of light source that contrasts with an environment in which near-eye display system 120 operates, or some combinations thereof. In embodiments where locators 126 are active components (e.g., LEDs or other types of light emitting devices), locators 126 may emit light in the visible band (e.g., about 380 nm to 750 nm), in the infrared (IR) band (e.g., about 750 nm to 1 mm), in the ultraviolet band (e.g., about 10 nm to about 380 nm), in another portion of the electromagnetic spectrum, or in any combination of portions of the electromagnetic spectrum.

Imaging device 150 may be part of near-eye display system 120 or may be external to near-eye display system 120. Imaging device 150 may generate slow calibration data based on calibration parameters received from console 110. Slow calibration data may include one or more images showing observed positions of locators 126 that are detectable by imaging device 150. Imaging device 150 may include one or more cameras, one or more video cameras, any other device capable of capturing images including one or more of locators 126, or some combinations thereof. Additionally, imaging device 150 may include one or more filters (e.g., to increase signal to noise ratio). Imaging device 150 may be configured to detect light emitted or reflected from locators 126 in a field of view of imaging device 150. In embodiments where locators 126 include passive elements (e.g., retroreflectors), imaging device 150 may include a light source that illuminates some or all of locators 126, which may retro-reflect the light to the light source in imaging device 150. Slow calibration data may be communicated from imaging device 150 to console 110, and imaging device 150 may receive one or more calibration parameters from console 110 to adjust one or more imaging parameters (e.g., focal length, focus, frame rate, sensor temperature, shutter speed, aperture, etc.).

Position sensors 128 may generate one or more measurement signals in response to motion of near-eye display system 120. Examples of position sensors 128 may include accelerometers, gyroscopes, magnetometers, other motion-detecting or error-correcting sensors, or some combinations thereof. For example, in some embodiments, position sensors 128 may include multiple accelerometers to measure translational motion (e.g., forward/back, up/down, or left/right) and multiple gyroscopes to measure rotational motion (e.g., pitch, yaw, or roll). In some embodiments, various position sensors may be oriented orthogonally to each other.

IMU 132 may be an electronic device that generates fast calibration data based on measurement signals received from one or more of position sensors 128. Position sensors 128 may be located external to IMU 132, internal to IMU 132, or some combination thereof. Based on the one or more measurement signals from one or more position sensors 128, IMU 132 may generate fast calibration data indicating an estimated position of near-eye display system 120 relative to an initial position of near-eye display system 120. For example, IMU 132 may integrate measurement signals received from accelerometers over time to estimate a velocity vector and integrate the velocity vector over time to determine an estimated position of a reference point on near-eye display system 120. Alternatively, IMU 132 may provide the sampled measurement signals to console 110, which may determine the fast calibration data. While the reference point may generally be defined as a point in space, in various embodiments, the reference point may also be defined as a point within near-eye display system 120 (e.g., a center of IMU 132).

Eye-tracking system 130 may include one or more eye-tracking systems. Eye tracking may refer to determining an eye's position, including orientation and location of the eye, relative to near-eye display system 120. An eye-tracking system may include an imaging system to image one or more eyes and may generally include a light emitter, which may generate light that is directed to an eye such that light reflected by the eye may be captured by the imaging system. For example, eye-tracking system 130 may include a non-coherent or coherent light source (e.g., a laser diode) emitting light in the visible spectrum or infrared spectrum, and a camera capturing the light reflected by the user's eye. As another example, eye-tracking system 130 may capture reflected radio waves emitted by a miniature radar unit. Eye-tracking system 130 may use low-power light emitters that emit light at frequencies and intensities that would not injure the eye or cause physical discomfort. Eye-tracking system 130 may be arranged to increase contrast in images of an eye captured by eye-tracking system 130 while reducing the overall power consumed by eye-tracking system 130 (e.g., reducing power consumed by a light emitter and an imaging system included in eye-tracking system 130). For example, in some implementations, eye-tracking system 130 may consume less than 100 milliwatts of power.

Eye-tracking system 130 may be configured to estimate the orientation of the user's eye. The orientation of the eye may correspond to the direction of the user's gaze within near-eye display system 120. The orientation of the user's eye may be defined as the direction of the foveal axis, which is the axis between the fovea (an area on the retina of the eye with the highest concentration of photoreceptors) and the center of the eye's pupil. In general, when a user's eyes are fixed on a point, the foveal axes of the user's eyes intersect that point. The pupillary axis of an eye may be defined as the axis that passes through the center of the pupil and is perpendicular to the corneal surface. In general, even though the pupillary axis and the foveal axis intersect at the center of the pupil, the pupillary axis may not directly align with the foveal axis. For example, the orientation of the foveal axis may be offset from the pupillary axis by approximately −1° to 8° laterally and about ±4° vertically (which may be referred to as kappa angles, which may vary from person to person). Because the foveal axis is defined according to the fovea, which is located in the back of the eye, the foveal axis may be difficult or impossible to measure directly in some eye-tracking embodiments. Accordingly, in some embodiments, the orientation of the pupillary axis may be detected and the foveal axis may be estimated based on the detected pupillary axis.

In general, the movement of an eye corresponds not only to an angular rotation of the eye, but also to a translation of the eye, a change in the torsion of the eye, and/or a change in the shape of the eye. Eye-tracking system 130 may also be configured to detect the translation of the eye, which may be a change in the position of the eye relative to the eye socket. In some embodiments, the translation of the eye may not be detected directly, but may be approximated based on a mapping from a detected angular orientation. Translation of the eye corresponding to a change in the eye's position relative to the eye-tracking system due to, for example, a shift in the position of near-eye display system 120 on a user's head, may also be detected. Eye-tracking system 130 may also detect the torsion of the eye and the rotation of the eye about the pupillary axis. Eye-tracking system 130 may use the detected torsion of the eye to estimate the orientation of the foveal axis from the pupillary axis. In some embodiments, eye-tracking system 130 may also track a change in the shape of the eye, which may be approximated as a skew or scaling linear transform or a twisting distortion (e.g., due to torsional deformation). In some embodiments, eye-tracking system 130 may estimate the foveal axis based on some combinations of the angular orientation of the pupillary axis, the translation of the eye, the torsion of the eye, and the current shape of the eye.

In some embodiments, eye-tracking system 130 may include multiple emitters or at least one emitter that can project a structured light pattern on all portions or a portion of the eye. The structured light pattern may be distorted due to the shape of the eye when viewed from an offset angle. Eye-tracking system 130 may also include at least one camera that may detect the distortions (if any) of the structured light pattern projected onto the eye. The camera may be oriented on a different axis to the eye than the emitter. By detecting the deformation of the structured light pattern on the surface of the eye, eye-tracking system 130 may determine the shape of the portion of the eye being illuminated by the structured light pattern. Therefore, the captured distorted light pattern may be indicative of the 3D shape of the illuminated portion of the eye. The orientation of the eye may thus be derived from the 3D shape of the illuminated portion of the eye. Eye-tracking system 130 can also estimate the pupillary axis, the translation of the eye, the torsion of the eye, and the current shape of the eye based on the image of the distorted structured light pattern captured by the camera.

Near-eye display system 120 may use the orientation of the eye to, e.g., determine an inter-pupillary distance (IPD) of the user, determine gaze directions, introduce depth cues (e.g., blur image outside of the user's main line of sight), collect heuristics on the user interaction in the VR media (e.g., time spent on any particular subject, object, or frame as a function of exposed stimuli), some other functions that are based in part on the orientation of at least one of the user's eyes, or some combination thereof. Because the orientation may be determined for both eyes of the user, eye-tracking system 130 may be able to determine where the user is looking. For example, determining a direction of a user's gaze may include determining a point of convergence based on the determined orientations of the user's left and right eyes. A point of convergence may be the point where the two foveal axes of the user's eyes intersect. The direction of the user's gaze may be the direction of a line passing through the point of convergence and the mid-point between the pupils of the user's eyes.

Input/output interface 140 may be a device that allows a user to send action requests to console 110. An action request may be a request to perform a particular action. For example, an action request may be to start or to end an application or to perform a particular action within the application. Input/output interface 140 may include one or more input devices. Example input devices may include a keyboard, a mouse, a game controller, a glove, a button, a touch screen, or any other suitable device for receiving action requests and communicating the received action requests to console 110. An action request received by the input/output interface 140 may be communicated to console 110, which may perform an action corresponding to the requested action. In some embodiments, input/output interface 140 may provide haptic feedback to the user in accordance with instructions received from console 110. For example, input/output interface 140 may provide haptic feedback when an action request is received, or when console 110 has performed a requested action and communicates instructions to input/output interface 140. In some embodiments, imaging device 150 may be used to track input/output interface 140, such as tracking the location or position of a controller (which may include, for example, an IR light source) or a hand of the user to determine the motion of the user. In some embodiments, near-eye display 120 may include one or more imaging devices (e.g., imaging device 150) to track input/output interface 140, such as tracking the location or position of a controller or a hand of the user to determine the motion of the user.

Console 110 may provide content to near-eye display system 120 for presentation to the user in accordance with information received from one or more of imaging device 150, near-eye display system 120, and input/output interface 140. In the example shown in FIG. 1, console 110 may include an application store 112, a headset tracking module 114, an artificial reality engine 116, and eye-tracking module 118. Some embodiments of console 110 may include different or additional modules than those described in conjunction with FIG. 1. Functions further described below may be distributed among components of console 110 in a different manner than is described here.

In some embodiments, console 110 may include a processor and a non-transitory computer-readable storage medium storing instructions executable by the processor. The processor may include multiple processing units executing instructions in parallel. The computer-readable storage medium may be any memory, such as a hard disk drive, a removable memory, or a solid-state drive (e.g., flash memory or dynamic random access memory (DRAM)). In various embodiments, the modules of console 110 described in conjunction with FIG. 1 may be encoded as instructions in the non-transitory computer-readable storage medium that, when executed by the processor, cause the processor to perform the functions further described below.

Application store 112 may store one or more applications for execution by console 110. An application may include a group of instructions that, when executed by a processor, generates content for presentation to the user. Content generated by an application may be in response to inputs received from the user via movement of the user's eyes or inputs received from the input/output interface 140. Examples of the applications may include gaming applications, conferencing applications, video playback application, or other suitable applications.

Headset tracking module 114 may track movements of near-eye display system 120 using slow calibration information from imaging device 150. For example, headset tracking module 114 may determine positions of a reference point of near-eye display system 120 using observed locators from the slow calibration information and a model of near-eye display system 120. Headset tracking module 114 may also determine positions of a reference point of near-eye display system 120 using position information from the fast calibration information. Additionally, in some embodiments, headset tracking module 114 may use portions of the fast calibration information, the slow calibration information, or some combination thereof, to predict a future location of near-eye display system 120. Headset tracking module 114 may provide the estimated or predicted future position of near-eye display system 120 to artificial reality engine 116.

Headset tracking module 114 may calibrate the artificial reality system environment 100 using one or more calibration parameters, and may adjust one or more calibration parameters to reduce errors in determining the position of near-eye display system 120. For example, headset tracking module 114 may adjust the focus of imaging device 150 to obtain a more accurate position for observed locators on near-eye display system 120. Moreover, calibration performed by headset tracking module 114 may also account for information received from IMU 132. Additionally, if tracking of near-eye display system 120 is lost (e.g., imaging device 150 loses line of sight of at least a threshold number of locators 126), headset tracking module 114 may re-calibrate some or all of the calibration parameters.

Artificial reality engine 116 may execute applications within artificial reality system environment 100 and receive position information of near-eye display system 120, acceleration information of near-eye display system 120, velocity information of near-eye display system 120, predicted future positions of near-eye display system 120, or some combination thereof from headset tracking module 114. Artificial reality engine 116 may also receive estimated eye position and orientation information from eye-tracking module 118. Based on the received information, artificial reality engine 116 may determine content to provide to near-eye display system 120 for presentation to the user. For example, if the received information indicates that the user has looked to the left, artificial reality engine 116 may generate content for near-eye display system 120 that reflects the user's eye movement in a virtual environment. Additionally, artificial reality engine 116 may perform an action within an application executing on console 110 in response to an action request received from input/output interface 140, and provide feedback to the user indicating that the action has been performed. The feedback may be visual or audible feedback via near-eye display system 120 or haptic feedback via input/output interface 140.

Eye-tracking module 118 may receive eye-tracking data from eye-tracking system 130 and determine the position of the user's eye based on the eye-tracking data. The position of the eye may include an eye's orientation, location, or both relative to near-eye display system 120 or any clement thereof. Because the eye's axes of rotation change as a function of the eye's location in its socket, determining the eye's location in its socket may allow eye-tracking module 118 to more accurately determine the eye's orientation.

In some embodiments, eye-tracking module 118 may store a mapping between images captured by eye-tracking system 130 and eye positions to determine a reference eye position from an image captured by eye-tracking system 130. Alternatively or additionally, eye-tracking module 118 may determine an updated eye position relative to a reference eye position by comparing an image from which the reference eye position is determined to an image from which the updated eye position is to be determined. Eye-tracking module 118 may determine eye position using measurements from different imaging devices or other sensors. For example, eye-tracking module 118 may use measurements from a slow eye-tracking system to determine a reference eye position, and then determine updated positions relative to the reference eye position from a fast eye-tracking system until a next reference eye position is determined based on measurements from the slow eye-tracking system.

Eye-tracking module 118 may also determine eye calibration parameters to improve precision and accuracy of eye tracking. Eye calibration parameters may include parameters that may change whenever a user dons or adjusts near-eye display system 120. Example eye calibration parameters may include an estimated distance between a component of eye-tracking system 130 and one or more parts of the eye, such as the eye's center, pupil, cornea boundary, or a point on the surface of the eye. Other example eye calibration parameters may be specific to a particular user and may include an estimated average eye radius, an average corneal radius, an average sclera radius, a map of features on the eye surface, and an estimated eye surface contour. In embodiments where light from the outside of near-eye display system 120 may reach the eye (as in some augmented reality applications), the calibration parameters may include correction factors for intensity and color balance due to variations in light from the outside of near-eye display system 120. Eye-tracking module 118 may use eye calibration parameters to determine whether the measurements captured by eye-tracking system 130 would allow eye-tracking module 118 to determine an accurate eye position (also referred to herein as “valid measurements”). Invalid measurements, from which eye-tracking module 118 may not be able to determine an accurate eye position, may be caused by the user blinking, adjusting the headset, or removing the headset, and/or may be caused by near-eye display system 120 experiencing greater than a threshold change in illumination due to external light. In some embodiments, at least some of the functions of eye-tracking module 118 may be performed by eye-tracking system 130.

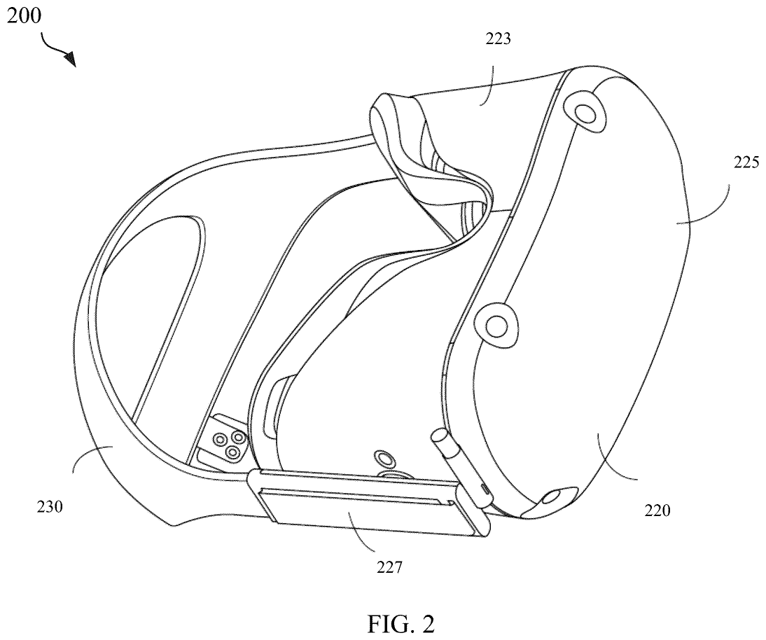

FIG. 2 is a perspective view of an example of a near-eye display system in the form of a head-mounted display (HMD) device 200 for implementing some of the examples disclosed herein. HMD device 200 may be a part of, e.g., a virtual reality (VR) system, an augmented reality (AR) system, a mixed reality (MR) system, or some combinations thereof. HMD device 200 may include a body 220 and a head strap 230. FIG. 2 shows a bottom side 223, a front side 225, and a left side 227 of body 220 in the perspective view. Head strap 230 may have an adjustable or extendible length. There may be a sufficient space between body 220 and head strap 230 of HMD device 200 for allowing a user to mount HMD device 200 onto the user's head. In various embodiments, HMD device 200 may include additional, fewer, or different components. For example, in some embodiments, HMD device 200 may include eyeglass temples and temples tips as shown in, for example, FIG. 2, rather than head strap 230.

HMD device 200 may present to a user media including virtual and/or augmented views of a physical, real-world environment with computer-generated elements. Examples of the media presented by HMD device 200 may include images (e.g., two-dimensional (2D) or three-dimensional (3D) images), videos (e.g., 2D or 3D videos ), audios, or some combinations thereof. The images and videos may be presented to each eye of the user by one or more display assemblies (not shown in FIG. 2) enclosed in body 220 of HMD device 200. In various embodiments, the one or more display assemblies may include a single electronic display panel or multiple electronic display panels (e.g., one display panel for each eye of the user). Examples of the electronic display panel(s) may include, for example, a liquid crystal display (LCD), an organic light emitting diode (OLED) display, an inorganic light emitting diode (ILED) display, a micro light emitting diode (μLED) display, an active-matrix organic light emitting diode (AMOLED) display, a transparent organic light emitting diode (TOLED) display, some other display, or some combinations thereof. HMD device 200 may include two eye box regions.

In some implementations, HMD device 200 may include various sensors (not shown), such as depth sensors, motion sensors, position sensors, and eye-tracking sensors. Some of these sensors may use a structured light pattern for sensing. In some implementations, HMD device 200 may include an input/output interface for communicating with a console. In some implementations, HMD device 200 may include a virtual reality engine (not shown) that can execute applications within HMD device 200 and receive depth information, position information, acceleration information, velocity information, predicted future positions, or some combination thereof of HMD device 200 from the various sensors. In some implementations, the information received by the virtual reality engine may be used for producing a signal (e.g., display instructions) to the one or more display assemblies. In some implementations, HMD device 200 may include locators (not shown, such as locators 126) located in fixed positions on body 220 relative to one another and relative to a reference point. Each of the locators may emit light that is detectable by an external imaging device.

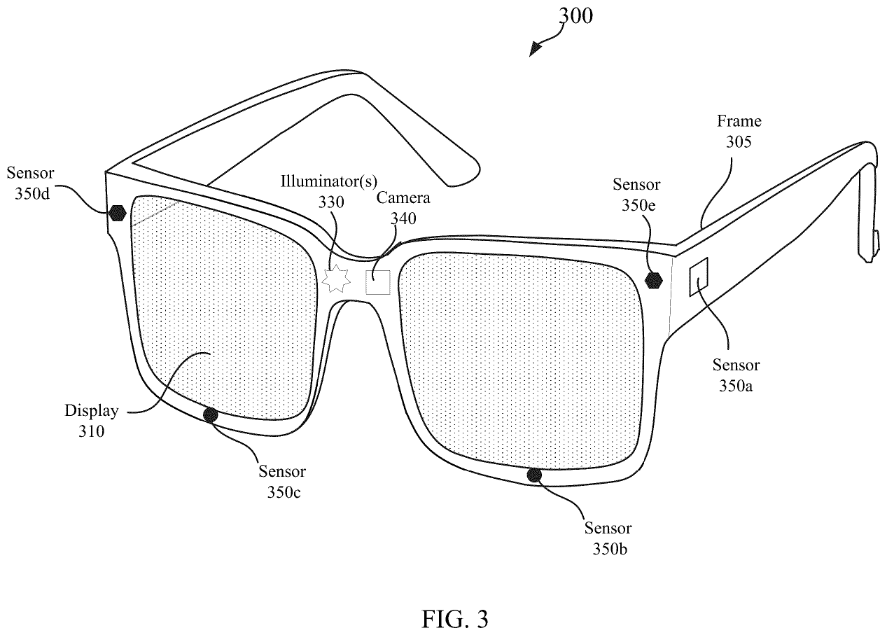

FIG. 3 is a perspective view of an example of a near-eye display system 300 in the form of a pair of glasses for implementing some of the examples disclosed herein. Near-eye display system 300 may be a specific implementation of near-eye display system 120 of FIG. 1, and may be configured to operate as a virtual reality display, an augmented reality display, and/or a mixed reality display. Near-eye display system 300 may include a frame 305 and a display 310. Display 310 may be configured to present content to a user. In some embodiments, display 310 may include display electronics and/or display optics. For example, as described above with respect to near-eye display system 120 of FIG. 1, display 310 may include an LCD display panel, an LED display panel, or an optical display panel (e.g., a waveguide display assembly).

Near-eye display system 300 may further include various sensors 350a, 350b, 350c, 350d, and 350e on or within frame 305. In some embodiments, sensors 350a-350e may include one or more depth sensors, motion sensors, position sensors, inertial sensors, or ambient light sensors. In some embodiments, sensors 350a-350e may include one or more image sensors configured to generate image data representing different fields of views in different directions. In some embodiments, sensors 350a-350e may be used as input devices to control or influence the displayed content of near-eye display system 300, and/or to provide an interactive VR/AR/MR experience to a user of near-eye display system 300. In some embodiments, sensors 350a-350e may also be used for stereoscopic imaging.

In some embodiments, near-eye display system 300 may further include one or more illuminators 330 to project light into the physical environment. The projected light may be associated with different frequency bands (e.g., visible light, infra-red light, ultra-violet light, etc.), and may serve various purposes. For example, illuminator(s) 330 may project light in a dark environment (or in an environment with low intensity of infra-red light, ultra-violet light, etc.) to assist sensors 350a-350e in capturing images of different objects within the dark environment. In some embodiments, illuminator(s) 330 may be used to project certain light pattern onto the objects within the environment. In some embodiments, illuminator(s) 330 may be used as locators, such as locators 126 described above with respect to FIG. 1.

In some embodiments, near-eye display system 300 may also include a high-resolution camera 340. Camera 340 may capture images of the physical environment in the field of view. The captured images may be processed, for example, by a virtual reality engine (e.g., artificial reality engine 116 of FIG. 1) to add virtual objects to the captured images or modify physical objects in the captured images, and the processed images may be displayed to the user by display 310 for AR or MR applications.

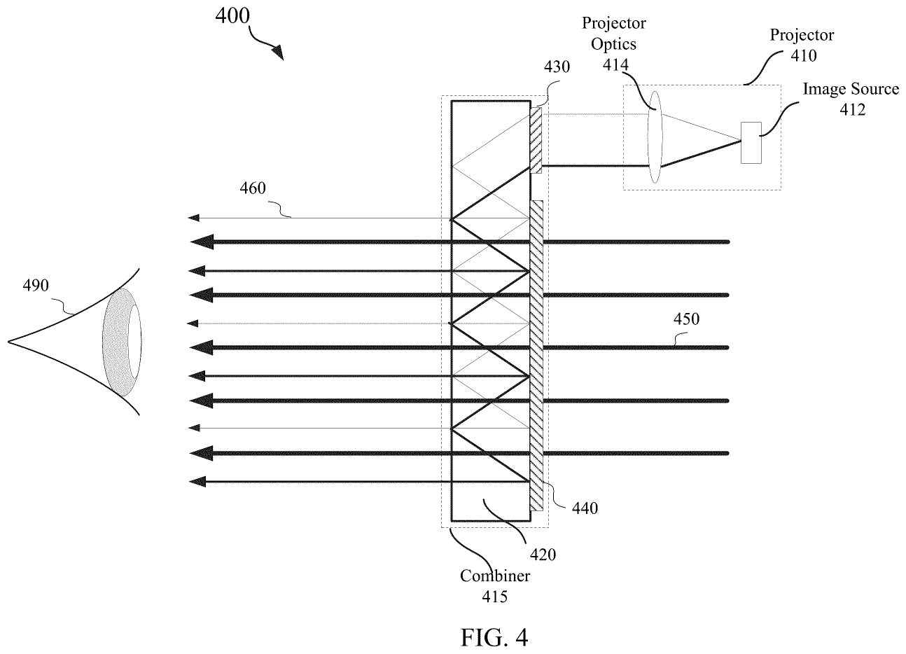

FIG. 4 illustrates an example of an optical see-through augmented reality system 400 using a waveguide display according to certain embodiments. Augmented reality system 400 may include a projector 410 and a combiner 415. Projector 410 may include a light source or image source 412 and projector optics 414. In some embodiments, image source 412 may include a plurality of pixels that displays virtual objects, such as an LCD display panel or an LED display panel. In some embodiments, image source 412 may include a light source that generates coherent or partially coherent light. For example, image source 412 may include a laser diode, a vertical cavity surface emitting laser, and/or a light emitting diode. In some embodiments, image source 412 may include a plurality of light sources each emitting a monochromatic image light corresponding to a primary color (e.g., red, green, or blue). In some embodiments, image source 412 may include an optical pattern generator, such as a spatial light modulator. Projector optics 414 may include one or more optical components that can condition the light from image source 412, such as expanding, collimating, scanning, or projecting light from image source 412 to combiner 415. The one or more optical components may include, for example, one or more lenses, liquid lenses, mirrors, apertures, and/or gratings. In some embodiments, projector optics 414 may include a liquid lens (e.g., a liquid crystal lens) with a plurality of electrodes that allows scanning of the light from image source 412.

Combiner 415 may include an input coupler 430 for coupling light from projector 410 into a substrate 420 of combiner 415. Input coupler 430 may include a volume holographic grating, a diffractive optical elements (DOE) (e.g., a surface-relief grating), a slanted surface of substrate 420, or a refractive coupler (e.g., a wedge or a prism). Input coupler 430 may have a coupling efficiency of greater than 30%, 50%, 75%, 90%, or higher for visible light. Light coupled into substrate 420 may propagate within substrate 420 through, for example, total internal reflection (TIR). Substrate 420 may be in the form of a lens of a pair of eyeglasses. Substrate 420 may have a flat or a curved surface, and may include one or more types of dielectric materials, such as glass, quartz, plastic, polymer, poly (methyl methacrylate) (PMMA), crystal, or ceramic. A thickness of the substrate may range from, for example, less than about 1 mm to about 10 mm or more. Substrate 420 may be transparent to visible light.

Substrate 420 may include or may be coupled to a plurality of output couplers 440 configured to extract at least a portion of the light guided by and propagating within substrate 420 from substrate 420, and direct extracted light 460 to an eye 490 of the user of augmented reality system 400. As input coupler 430, output couplers 440 may include grating couplers (e.g., volume holographic gratings or surface-relief gratings), other DOEs, prisms, etc. Output couplers 440 may have different coupling (e.g., diffraction) efficiencies at different locations. Substrate 420 may also allow light 450 from environment in front of combiner 415 to pass through with little or no loss. Output couplers 440 may also allow light 450 to pass through with little loss. For example, in some implementations, output couplers 440 may have a low diffraction efficiency for light 450 such that light 450 may be refracted or otherwise pass through output couplers 440 with little loss, and thus may have a higher intensity than extracted light 460. In some implementations, output couplers 440 may have a high diffraction efficiency for light 450 and may diffract light 450 to certain desired directions (i.e., diffraction angles) with little loss. As a result, the user may be able to view combined images of the environment in front of combiner 415 and virtual objects projected by projector 410.

In addition, as described above, in an artificial reality system, to improve user interaction with presented content, the artificial reality system may track the user's eye and modify or generate content based on a location or a direction in which the user is looking at. Tracking the eye may include tracking the position and/or shape of the pupil and/or the cornea of the eye, and determining the rotational position or gaze direction of the eye. One technique (referred to as Pupil Center Corneal Reflection or PCCR method) involves using NIR LEDs to produce glints on the eye cornea surface and then capturing images/videos of the eye region. Gaze direction can be estimated from the relative movement between the pupil center and glints. Various holographic optical elements may be used in an eye-tracking system for illuminating the user's eyes or collecting light reflected by the user's eye.

One example of the holographic optical elements used in an artificial reality system for eye tracking or image display may be a holographic volume Bragg grating, which may be recorded on a holographic material layer by exposing the holographic material layer to light patterns generated by the interference between two or more coherent light beams.

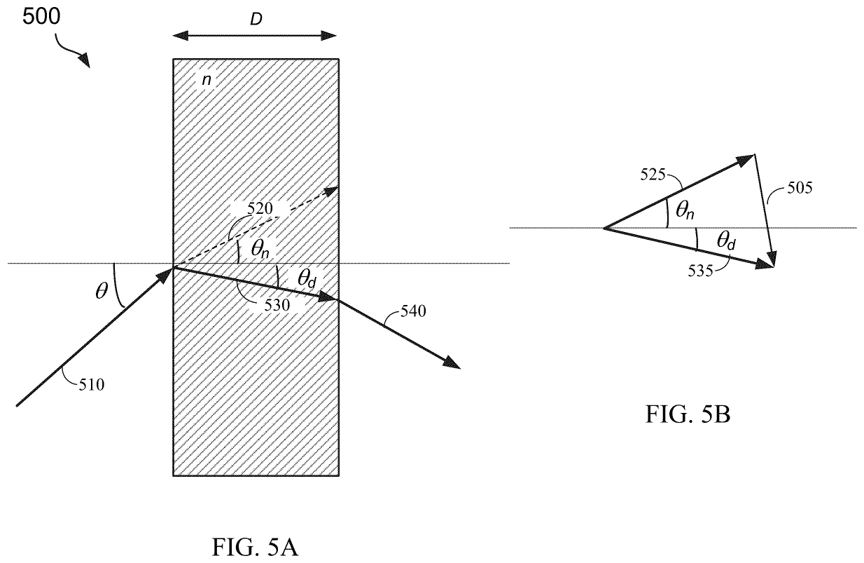

FIG. 5A illustrates an example of a volume Bragg grating (VBG) 500. Volume Bragg grating 500 shown in FIG. 5A may include a transmission holographic grating that has a thickness D. The refractive index n of volume Bragg grating 500 may be modulated at an amplitude n₁, and the grating period of volume Bragg grating 500 may be A. Incident light 510 having a wavelength λ may be incident on volume Bragg grating 500 at an incident angle θ, and may be refracted into volume Bragg grating 500 as incident light 520 that propagates at an angle θₙ in volume Bragg grating 500. Incident light 520 may be diffracted by volume Bragg grating 500 into diffraction light 530, which may propagate at a diffraction angle θ_{d} in volume Bragg grating 500 and may be refracted out of volume Bragg grating 500 as diffraction light 540.

FIG. 5B illustrates the Bragg condition for volume Bragg grating 500 shown in FIG. 5A. Vector 505 represents the grating vector \vec{G}, where |\vec{G}|=2π/Λ. Vector 525 represents the incident wave vector \vec{kₗ}, and vector 535 represents the diffract wave vector \vec{k_{d}}, where |\vec{kₗ}|=|\vec{k_{d}}|=2πn/λ. Under the Bragg phase-matching condition, \vec{kₗ}-\vec{k_{d}}=\vec{G}. Thus, for a given wavelength λ, there may only be one pair of incident angle θ (or θₙ) and diffraction angle θ_{d} that meets the Bragg condition perfectly. Similarly, for a given incident angle θ, there may only be one wavelength λ that meets the Bragg condition perfectly. As such, the diffraction may only occur in a small wavelength range and a small incident angle range. The diffraction efficiency, the wavelength selectivity, and the angular selectivity of volume Bragg grating 500 may be functions of thickness D of volume Bragg grating 500. For example, the full-width-half-magnitude (FWHM) wavelength range and the FWHM angle range of volume Bragg grating 500 at the Bragg condition may be inversely proportional to thickness D of volume Bragg grating 500, while the maximum diffraction efficiency at the Bragg condition may be a function sin²(α×n_{1×}D), where a is a coefficient. For a reflection volume Bragg grating, the maximum diffraction efficiency at the Bragg condition may be a function of tanh² (α×n₁×D).

In some embodiments, a multiplexed Bragg grating may be used to achieve the desired optical performance, such as a high diffraction efficiency and a large FOV for the full visible spectrum (e.g., from about 400 nm to about 700 nm, or from about 440 nm to about 650 nm). Each part of the multiplexed Bragg grating may be used to diffract light from a respective FOV range and/or within a respective wavelength range. Thus, in some designs, multiple volume Bragg gratings each recorded under a respective recording condition may be used.

The holographic optical elements described above may be recorded in a holographic material (e.g., photopolymer) layer. In some embodiments, the HOEs can be recorded first and then laminated on a substrate in a near-eye display system. In some embodiments, a holographic material layer may be coated or laminated on the substrate and the HOEs may then be recorded in the holographic material layer.

In general, to record a holographic optical element in a photosensitive material layer, two coherent beams may interfere with each other at certain angles to generate a unique interference pattern in the photosensitive material layer, which may in turn generate a unique refractive index modulation pattern in the photosensitive material layer, where the refractive index modulation pattern may correspond to the light intensity pattern of the interference pattern.

The photosensitive material layer may include, for example, silver halide emulsion, dichromated gelatin, photopolymers including photo-polymerizable monomers suspended in a polymer matrix, photorefractive crystals, and the like. One example of the photosensitive material layer for holographic recording is two-stage photopolymers.

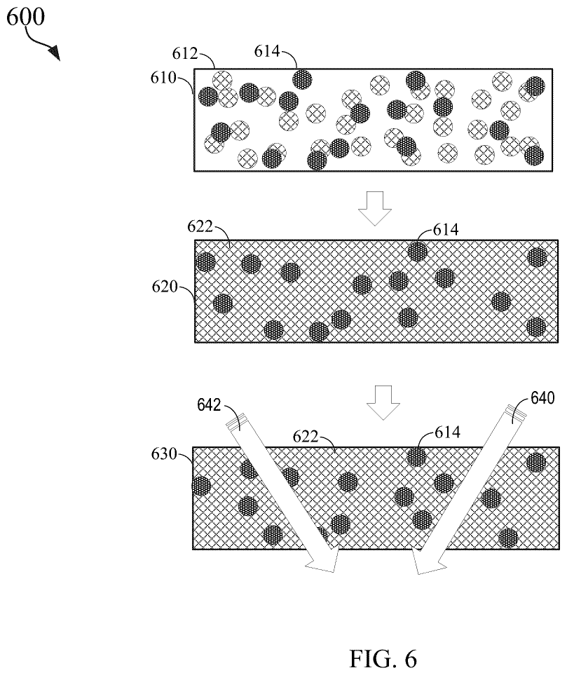

FIG. 6 illustrates an example of a holographic recording material including two-stage photopolymers. The raw material 610 of the two-stage photopolymers may be a resin including matrix precursors 612 and imaging components 614. Matrix precursors 612 in raw material 610 may include monomers that may be thermally or otherwise cured at the first stage to polymerize and to form a photopolymer film 620 that includes a cross-linked matrix formed by polymeric binders 622. Imaging components 614 may include writing monomers and polymerization initiating agents, such as photosensitizing dyes, initiators, and/or chain transfer agents. Thus, photopolymer film 620 may include polymeric binders 622, writing monomers (e.g., acrylate monomers), and initiating agents, such as photosensitizing dyes, initiators, and/or chain transfer agents. Polymeric binders 622 may act as the backbone or the support matrix for the writing monomers and initiating agents. For example, in some embodiments, polymeric binders 622 may include a low refractive index (e.g., <1.5) rubbery polymer (e.g., a polyurethane), which may provide mechanical support during the holographic exposure and ensure the refractive index modulation by the light pattern is permanently preserved.

Imaging components 614 including the writing monomers and the polymerization initiating agents may be dispersed in the support matrix. The writing monomers may serve as refractive index modulators. For example, the writing monomers may include high refractive index acrylate monomers which can react with the initiators and polymerize. The photosensitizing dyes may be used to absorb light and interact with the initiators to produce active species, such as radicals, cations (e.g., acids), or anion (e.g., bases). The active species (e.g., radicals) may initiate the polymerization by attacking a monomer. For example, in some monomers, one electron pair may be held securely between two carbons in a sigma bond and another electron pair may be more loosely held in a pi bond, and the free radical may use one electron from the pi bond to form a more stable bond with a first carbon atom in the two carbon atoms. The other electron from the pi bond may return to the second carbon atom in the two carbon atoms and turn the whole molecule into another radical. Thus, a monomer chain (e.g., a polymer) may be formed by adding additional monomers to the end of the monomer chain and transferring the radical to the end of the monomer chain to attack and add more monomers to the chain.

During the recording process (e.g., the second stage), an interference pattern generated by the interference between two coherent beams 640 and 642 may cause the photosensitizing dyes and the initiators in the bright fringes to generate active species, such as radicals, cations (e.g., acids), or anion (e.g., bases), from the initiators, where the active species (e.g., radicals) may transfer from the initiators to monomers and cause the polymerization of the monomers in the bright fringes as described above. The initiators or radicals may be bound to the polymer matrix when abstracting the hydrogen atoms on the polymer matrix. The radicals may be transferred to the ends of the chains of monomers to add more monomers to the chains. While the monomers in the bright fringes are attached to chains of monomers, monomers in the unexposed dark regions may diffuse to the bright fringes to enhance the polymerization. As a result, polymerization concentration and density gradients may be formed in photopolymer film 620, resulting in refractive index modulation in photopolymer film 620 due to the higher refractive index of the writing monomers. For example, areas with a higher concentration of monomers and polymerization may have a higher refractive index. Thus, a hologram or a holographic optical element 630 may be formed in photopolymer film 620.

During the exposure, a radical at the end of one monomer chain may combine with a radical at the end of another monomer chain to form a longer chain and terminate the polymerization. In addition to the termination due to radical combination, the polymerization may also be terminated by disproportionation of polymers, where a hydrogen atom from one chain may be abstracted to another chain to generate a polymer with a terminal unsaturated group and a polymer with a terminal saturated group. The polymerization may also be terminated due to interactions with impurities or inhibitors (e.g., oxygen). In addition, as the exposure and polymerization proceed, fewer monomers may be available for diffusion and polymerization, and thus the diffusion and polymerization may be suppressed. The polymerization may stop until there are no more monomers or until the monomer chains terminate for an exposure. After all or substantially all monomers have been polymerized, no more new holographic optical elements 630 (e.g., gratings) may be recorded in photopolymer film 620.

In some embodiments, the recorded holographic optical elements in the photosensitive material layer may be UV cured or thermally cured or enhanced, for example, for dye bleaching, completing polymerization, permanently fixing the recorded pattern, and enhancing the refractive index modulation. At the end of the process, a holographic optical element, such as a holographic grating, may be formed. The holographic grating may be a volume Bragg grating with a thickness of, for example, a few, or tens, or hundreds of microns.

To generate the desired light interference pattern for recording the HOEs, two or more coherent beams may generally be used, where one beam may be a reference beam and another beam may be an object beam that may have a desired wavefront profile. When the recorded HOEs are illuminated by the reference beam, the object beam with the desired wavefront profile may be reconstructed.

In some embodiments, the holographic optical elements may be used to diffract light outside of the visible band. For example, IR light or NIR light (e.g., at 940 nm or 850 nm) may be used for eye-tracking. Thus, the holographic optical elements may need to diffract IR or NIR light, but not the visible light. However, there may be very few holographic recording materials that are sensitive to infrared light. As such, to record a holographic grating that can diffract infrared light, recording light at a shorter wavelength (e.g., in visible or UV band, such as at about 660 nm, about 532 nm, about 514 nm, or about 457 nm) may be used, and the recording condition (e.g., the angles of the two interfering coherent beams) may be different from the reconstruction condition.

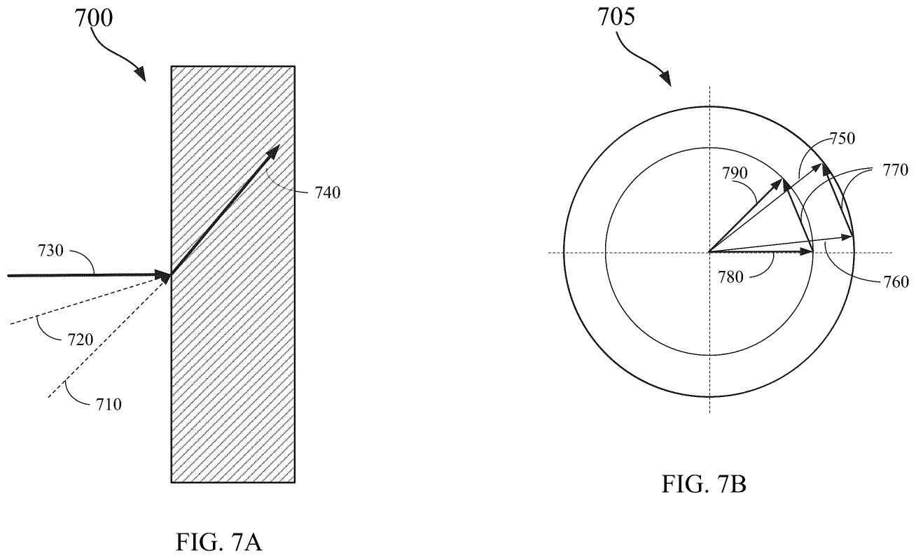

FIG. 7A illustrates the recording light beams for recording a volume Bragg grating 700 and the light beam reconstructed from volume Bragg grating 700. In the example illustrated, volume Bragg grating 700 may include a transmission volume hologram recorded using a reference beam 720 and an object beam 710 at a first wavelength, such as 660 nm. When a light beam 730 at a second wavelength (e.g., 940 nm) is incident on volume Bragg grating 700 at a 0° incident angle, the incident light beam 730 may be diffracted by volume Bragg grating 700 at a diffraction angle as shown by a diffracted beam 740.

FIG. 7B is an example of a holography momentum diagram 705 illustrating the wave vectors of recording beams and reconstruction beams and the grating vector of the recorded volume Bragg grating. FIG. 7B shows the Bragg matching conditions during the holographic grating recording and reconstruction. The length of wave vectors 750 and 760 of the recording beams (e.g., object beam 710 and reference beam 720) may be determined based on the recording light wavelength λ_{c} (e.g., 660 nm) according to 2πn/λ_{c}, where n is the average refractive index of holographic material layer. The directions of wave vectors 750 and 760 of the recording beams may be determined based on the desired grating vector K (770) such that wave vectors 750 and 760 and grating vector K (770) can form an isosceles triangle as shown in FIG. 7B. Grating vector K may have an amplitude 2π/Λ, where Λ is the grating period. Grating vector K may in turn be determined based on the desired reconstruction condition. For example, based on the desired reconstruction wavelength λᵣ (e.g., 940 nm) and the directions of the incident light beam (e.g., light beam 730 at) 0° and the desired diffracted light beam (e.g., diffracted beam 740), grating vector K (770) of volume Bragg grating 700 may be determined based on the Bragg condition, where wave vector 780 of the incident light beam (e.g., light beam 730) and wave vector 790 of the diffracted light beam (e.g., diffracted beam 740) may have an amplitude 2πn/λᵣ, and may form an isosceles triangle with grating vector K (770) as shown in FIG. 7B.

As described above, for a given wavelength, there may only be one pair of incident angle and diffraction angle that meets the Bragg condition perfectly. Similarly, for a given incident angle, there may only be one wavelength that meets the Bragg condition perfectly. When the incident angle of the reconstruction light beam is different from the incident angle that meets the Bragg condition of the volume Bragg grating or when the wavelength of the reconstruction light beam is different from the wavelength that meets the Bragg condition of the volume Bragg grating, the diffraction efficiency may be reduced as a function of the Bragg mismatch factor caused by the angular or wavelength detuning from the Bragg condition. As such, the diffraction may only occur in a small wavelength range and a small incident angle range.

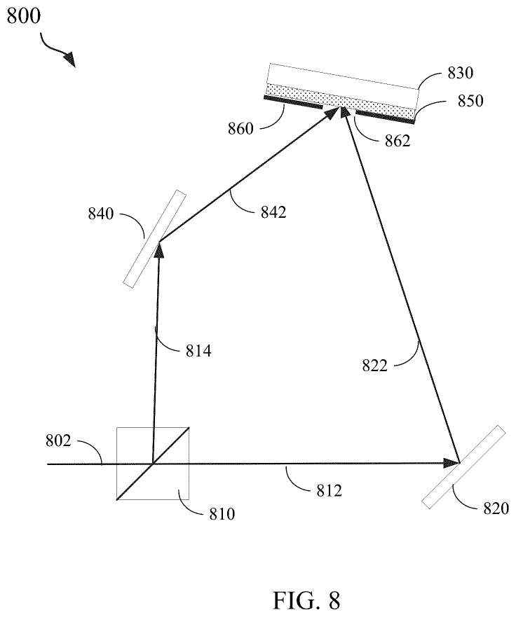

FIG. 8 illustrates an example of a holographic recording system 800 for recording holographic optical elements. Holographic recording system 800 includes a beam splitter 810 (e.g., a beam splitter cube), which may split an incident collimated laser beam 802 into two light beams 812 and 814 that are coherent and have similar intensities. Light beam 812 may be reflected by a first mirror 820 towards a plate 830 as shown by the reflected light beam 822. On another path, light beam 814 may be reflected by a second mirror 840. The reflected light beam 842 may be directed towards plate 830, and may interfere with light beam 822 at plate 830 to generate an interference pattern that may include bright fringes and dark fringes. In some embodiments, plate 830 may also be a mirror. A holographic recording material layer 850 may be formed on plate 830 or on a substrate mounted on plate 830. The interference pattern may cause the holographic optical element to be recorded in holographic recording material layer 850 as described above.

In some embodiments, a mask 860 may be used to record different HOEs at different regions of holographic recording material layer 850. For example, mask 860 may include an aperture 862 for the holographic recording and may be moved to place aperture 862 at different regions on holographic recording material layer 850 to record different HOEs at the different regions under different recording conditions (e.g., recording beams with different angles).

Holographic recording materials can be selected for specific applications based on some parameters of the holographic recording materials, such as the spatial frequency response, dynamic range, photosensitivity, physical dimensions, mechanical properties, wavelength sensitivity, and development or bleaching method for the holographic recording material.

The dynamic range indicates the refractive index change that can be achieved in a holographic recording material. The dynamic range may affect, for example, the thickness of the device to achieve a high efficiency, and the number of holograms that can be multiplexed in a holographic material layer. The dynamic range may be represented by the refractive index modulation (RIM), which may be one half of the total change in refractive index. In generally, a large refractive index modulation in the holographic optical elements is desired in order to improve the diffraction efficiency and record multiple holographic optical elements in a same holographic material layer. However, for holographic photopolymer materials, due to the solubility limitation of the monomers in the holographic photopolymer materials, the maximum achievable refractive index modulation or dynamic range may be limited.

The spatial frequency response is a measure of the feature size that the holographic material can record and may dictate the types of Bragg conditions that can be achieved. The spatial frequency response can be characterized by a modulation transfer function, which may be a curve depicting the sinusoidal waves of varying frequencies. In general, a single spatial frequency value may be used to represent the frequency response, which may indicate the spatial frequency value at which the refractive index modulation begins to drop or at which the refractive index modulation is reduced by 3 dB. The spatial frequency response may also be represented by lines/mm, line pairs/mm, or the period of the sinusoid.

The photosensitivity of the holographic recording material may indicate the photo-dosage used to achieve a certain efficiency, such as 100% (or 1% for photo-refractive crystals). The physical dimensions that can be achieved in a particular holographic material may affect the aperture size as well as the spectral selectivity of the HOE device. Physical parameters of holographic recording materials may include, for example, damage thresholds and environmental stability. The wavelength sensitivity may be used to select the light source for the recording setup and may also affect the minimum achievable period. Some materials may be sensitive to light in a wide wavelength range. Many holographic materials may need post-exposure development or bleaching. Development considerations may include how the holographic material is developed or otherwise processed after the recording.

To record holographic optical elements for artificial reality system, it may be desirable that the photopolymer material is sensitive to visible light, can produce a large refractive index modulation An (e.g., high dynamic range), and have temporally and spatially controllable reaction and/or diffusion of the monomers and/or polymers such that chain transfer and termination reactions can be suppressed.

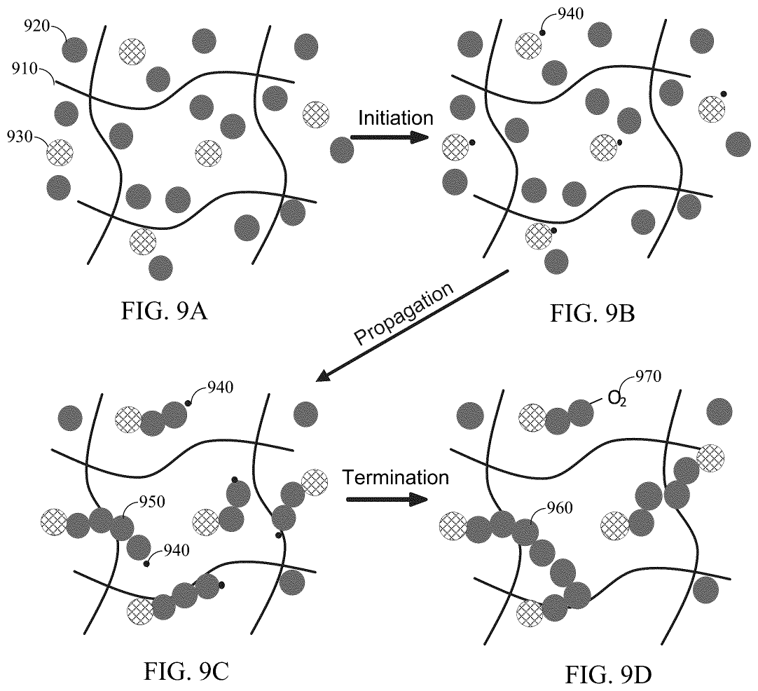

FIGS. 9A-9D illustrate an example of free radical polymerization in an example of a photopolymer material. Free radical polymerization can be used to polymerize a wide range of monomers, including olefins (e.g., ethylene and propylene) and vinyl monomers (e.g. vinylidene chloride, styrene, and methyl methacrylate), and is less sensitive to reactant impurities than, for example, anionic polymerization. Free radical polymerization generally includes the initiation, propagation, and termination of a monomer chain. In free radical polymerization, during the polymerization processes, monomer chains may be continuously initiated, propagated, and terminated.

FIG. 9A illustrates the photopolymer material before polymerization. The photopolymer material shown in FIG. 9A may include a polymer matrix 910 (e.g., polyurethane), unreacted writing monomers 920 (e.g., acrylate monomers), and initiators 930. As described above, in some embodiments, the photopolymer material may also include some photosensitizing dyes and/or chain transfer agents (not shown). Unreacted writing monomers 920 and initiators 930 may be dispersed in polymer matrix 910.

FIG. 9B illustrates the initiation of monomer chains, where radicals 940 are generated. Radicals for polymerization may be generated by, for example, photolysis, thermal decomposition, ionizing radiation, electrolysis, and the like. In the example shown in FIG. 9B, radicals 940 may be generated from the initiators immediately upon exposure to holographic recording light, which may cleave a bond in the initiators to produce the radicals.

FIG. 9C illustrates the propagation of the monomer chains, where radicals 940 may initiate the polymerization and propagate to chain ends to add more monomers. As described above, radicals 940 may initiate the polymerization by attacking a monomer 920. For example, in some monomers, an electron pair may be loosely held in a pi bond between two carbon atoms, and a radical 940 may use one electron from the pi bond to form a more stable bond with a first one of the two carbon atom. The other electron from the pi bond may return to the second carbon atom and turn the whole molecule into another radical. Thus, a monomer chain 950 may start to be formed by adding additional monomers 920 to the end of monomer chain 950 and transferring radical 940 to the end of monomer chain 950 to add more monomers 920 to the chain. As described above with respect to FIG. 6, initiators 930 or radicals 940 may react with and attach to polymer matrix 910 by hydrogen abstraction and chain transfer reactions, such that monomer chains 950 attached to the initiators may be attached to polymer matrix 910 through the initiator.

FIG. 9D illustrates the termination of the monomer chains, where a radical 940 at the end of a monomer chain 950 may combine, for example, with a radical 940 at the end of another monomer chain 950 to form a longer monomer chain 960, or with inhibiting species 970 (e.g., O₂). In some embodiments, the polymerization may also be terminated by disproportionation of polymers, where a hydrogen atom from one chain end may be abstracted to another chain end to generate a polymer with a terminal unsaturated group and a polymer with a terminal saturated group.

The performance of a holographic photopolymer may depend on how species diffuse and react during polymerization. In free radical polymerization, the polymerization and diffusion generally occur simultaneously in a relatively uncontrolled fashion, which may lead to some undesirable results.

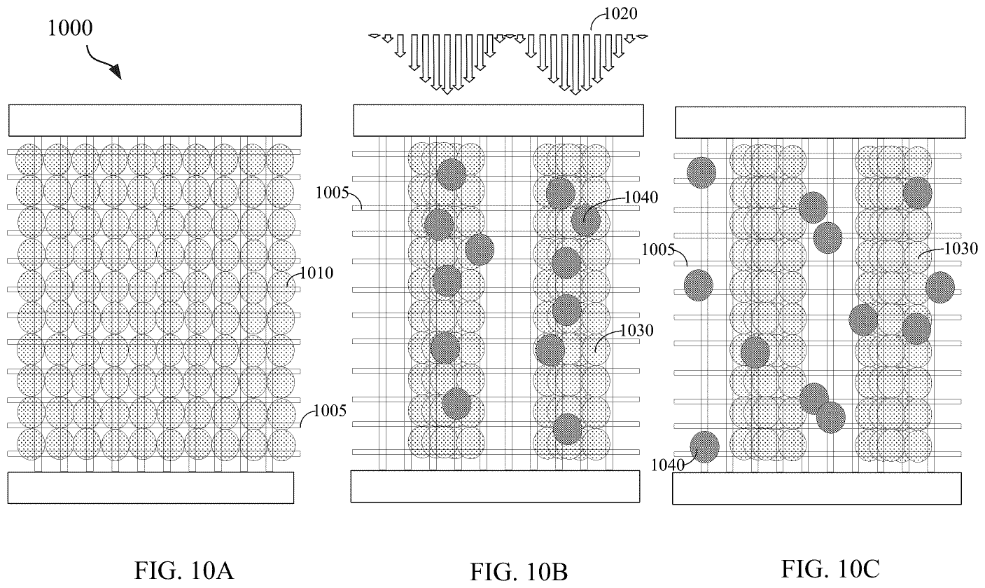

FIGS. 10A-10C illustrate an example of recording a holographic optical element in an uncontrolled photopolymer material layer 1000. FIG. 10A illustrates the unexposed photopolymer material layer 1000 that may include monomers 1010 suspended in a resin that may include a supporting polymer matrix 1005 (e.g., a cross-linked matrix formed by polymeric binders 622). Monomers 1010 may be substantially evenly distributed within photopolymer material layer 1000.

FIG. 10B illustrates an example of monomer diffusion and polymerization during holographic recording. When photopolymer material layer 1000 is exposed to a light pattern 1020, monomers 1010 may diffuse to the bright fringes in photopolymer material layer 1000 and polymerize to form polymers 1030 and 1040 in the bright fringes as described above. Some polymers, such as polymers 1030 may be bound to polymer matrix 1005. Some polymers, such as polymers 1040, may not be bound to polymer matrix 1005.

FIG. 10C illustrates an example of polymer diffusion after the holographic recording. As described above, some polymers 1040 that are formed in the bright fringes during the exposure and are not bound to polymer matrix 1005 may be free to diffuse in photopolymer material layer 1000. Some polymers 1040 may diffuse out of the exposed regions (e.g., the bright fringes) into unexposed regions, which may blur the resultant fringes of different refractive indices. In some cases, when the concentration of radicals on the exposed region is high, some unterminated radicals or radicals unattached to polymer matrix 1005 may also diffuse into the unexposed regions and cause polymerization in the unexposed regions. Thus, the diffusion of the unbound polymers or radicals into the unexposed regions may reduce the refractive index modulation Δn, the diffraction efficiency, and the minimum pitch of the recorded holographic optical elements.

In addition, during the exposure, the refractive index modulation Δn caused by the immediate initiation and polymerization may form intermediate holographic optical elements in the photopolymer material layer. The intermediate holographic optical elements may change the exposure light pattern in the photopolymer material layer, such as scattering or diffracting light in the exposure light pattern, which may lead to the formation of noisy gratings and cause haze and a loss of clarity in an optical system that uses such a holographic optical element, such as a waveguide display or eye-tracking system.

Furthermore, when the radical polymerization is uncontrolled (e.g., the polymerization continues after the exposure) and a series of exposures with constant dose or exposure is used to create a multiplexed hologram, the first exposure may consume most of the monomers, leading to an exponential decrease in refractive index modulation and diffraction efficiency for each subsequent exposure. Thus, a complicated dose scheduling procedure may be needed to balance the diffraction efficiency of the holograms in a multiplexed hologram.

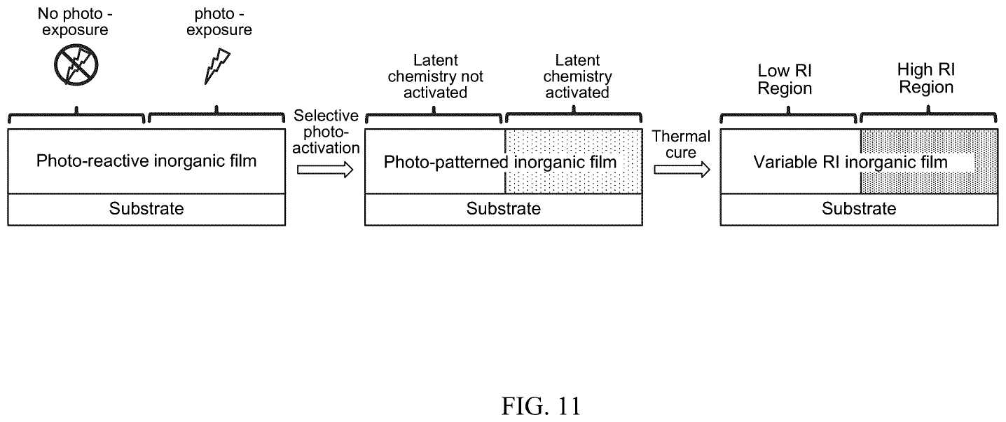

FIG. 11 illustrates an example of a process of generating RI modulation in an optical film. Photo-reactive materials that can have a local change in refractive index (RI) upon light excitation can be used to record Volume Bragg Gratings (VBG), holographic pattern, or create RI gradients in an optical film or coating as shown in FIG. 11. These materials can be used as Waveguide (WG) components in VR/AR/MR devices, wherein the photo-generated pattern controls the refraction and diffraction efficiency of light as it travels through the coating. In order to increase the efficiency of the WG device, the WG device may need to have certain characteristics.

For example, it may be desirable that the WG device has a large RI contrast or RI modulation (Δn) between photo-exposed areas and unexposed areas (e.g., Δn>0.05). This is because the higher the Δn, the higher the diffraction efficiency of the WG device may achieve. Both photo-exposed and unexposed areas need to be transparent to visible light after the material is fully processed (e.g., with absorption <0.1%/100 nm) because, for the coating to allow total internal reflection (TIR) with minimal absorption losses, the material should not be capable of electronic absorption of the light traveling through it. Otherwise, if either the photo-exposed or unexposed areas can absorb visible light, the efficiency of the WG display will be lowered. The thickness difference between photo-exposed and unexposed areas needs to be minimized to prevent surface scattering and diffraction (e.g., <20% of total coating thickness). More specifically, variations in coating thickness along the length of the WG may lead to optical artifacts, such as ghost images, or decreased image quality, such as pupil swim. Furthermore, periodic variation in the coating thickness, such as distinct thickness changes in the exposed regions, may act as surface relief gratings having their own diffractive behavior and thus disrupting the functionality of the overall WG display system.

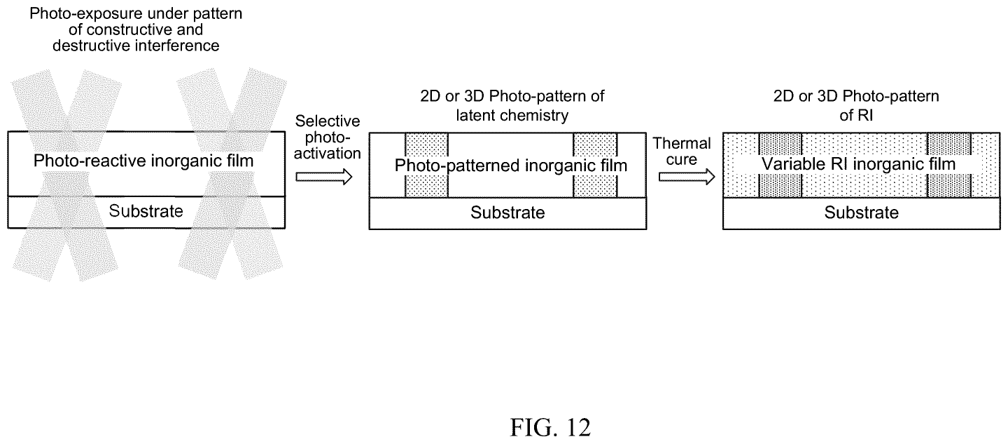

In addition, the photo-exposure should lead to a pattern of chemical or thermal reactivity that only produces a distinct change in RI index after the material undergoes post-processing. This behavior is referred to as photo-induced latent chemistry, where the photo-exposure process itself does not lead to a significant change in RI. Instead, it leaves behind a pattern of reactivity that is exploited in a subsequent step, such as thermal annealing. This latent chemistry behavior is particularly important when undergoing photo-exposure via light patterns formed by constructive and destructive interference or when it is critical to achieve nm-scale resolution between photo-exposed and unexposed areas as shown in FIG. 12. The reason is that the generation of a local An can itself diffract the light that is used to photo-pattern the material, thereby leading to parasitic grating formation or other aberrations in the diffraction and refraction behavior of the pattern. By de-coupling photo-excitation from An formation into two separate processing steps (photo-excitation and post-processing), the photo-reactive material can be exposed for as long as needed, without compromising the An pattern quality.

Furthermore, photo-excitation or post-processing should not entail the long-range (e.g., >10 nm) reorganization of components within the material, so as to prevent potential scattering issues. That is, if photo-exposure or post-processing result in displacement of a given component, such as a particle or a growing organic polymer chain, there will be a significant risk that the components agglomerate into units that are larger than 1/10 of the wavelength of light. As a result, the agglomerates may scatter light as the light travels through the optical coating, and the image quality of the WG display will be severely impacted.

Therefore, there is a need for materials that can be incorporated into WG devices as optical coatings, and can react to photo-excitation by creating a pattern of latent chemistry that leads to a large An upon post-processing. These materials should be fully transparent in both photo-exposed and nonexposed areas once post-processing is completed, and they should result in minimal thickness variations within all areas of the coating.

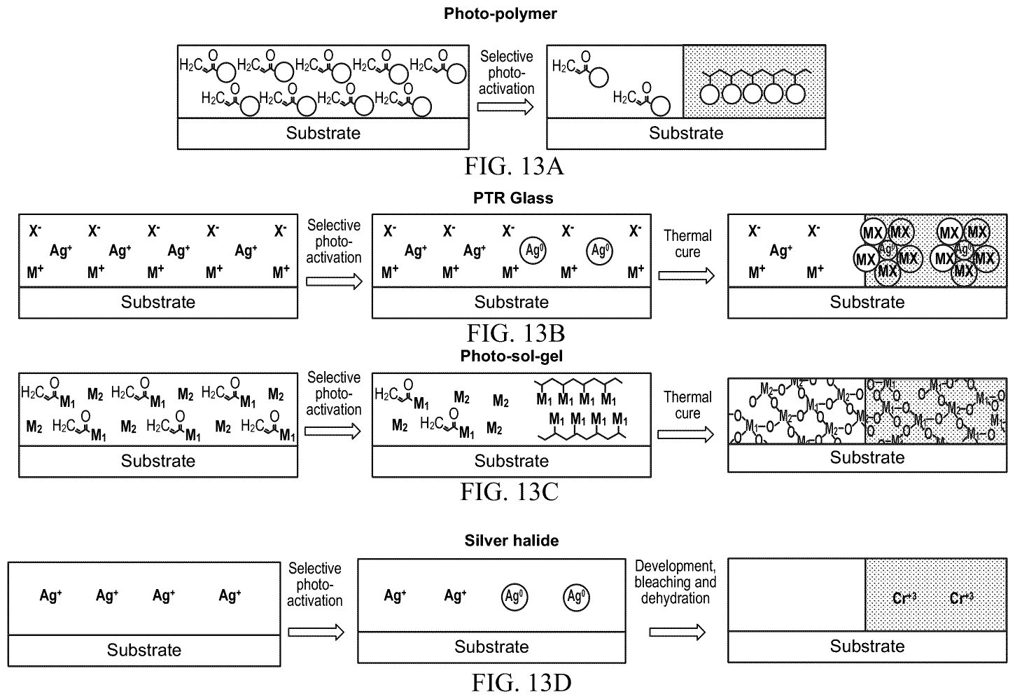

FIGS. 13A-13D illustrate examples of materials that may be utilized to record holographic optical elements (e.g., VBG) or holographic patterns. The most common material platform utilized to create VBG or other holographic patterns within optical films are organic photopolymers as shown in FIG. 13A and described above with respect to FIGS. 9A-10C. These materials are typically composed of two distinct organic components. The first one is a photo-reactive monomer or oligomer that can be polymerized via light excitation. If excitation only occurs in specific regions of the film, the monomer will be locally consumed into a growing polymer chain, triggering the displacement of more monomer away from the unexposed areas and depleting them of this component. Since this monomer typically has a different RI, as compared to the rest of the overall material, the movement of the photo-reactive monomer across the film induced by local photo-excitation will also lead to an RI gradient. The second component in the materials in a polymer that provides support for the photo-reactive monomer, allowing it to diffuse and photo-polymerize, while minimizing thickness and mechanical properties variations that would occur in the absence of a scaffold. This support component does not react with light, and can be fully cured of polymerized in a subsequent thermal step.

The limitations of these photo-polymer organic materials may be the result of relying on large-scale displacement of components to generate a pattern of optical properties. That is, internal diffusion of the photo-reactive monomer is limited by the thermomechanical and rheological properties of the mixture. As the viscosity, glass transition temperature Tg, and permeability of the scaffold decreases, the diffusion capabilities improve at the expense of mechanical stability and recording fidelity. Furthermore, the localization of the reacted photo-active component can lead to aggregation into scattering domains, significant local thickness variation, and deformation of the shape of the photo-recorded features.

In addition, the fact that photo-patterning is not achieved via latent chemistry, but instead actively changes local optical properties, leads to further patterning limitations. That is, the fact that the material actively shifts local RI as it is photo-excited also means that exposure time can only be increased at the expense of parasitic feature formation and recording density.

The organic nature of these photo-reactive polymers also means that it is challenging to maintain high flow and diffusability while also increasing the base RI of each component significantly >1.5. That is, increasing RI in organic components typically entails incorporating rigid, aromatic, or larger heteroatom moieties that usually reduce flow. Since RI changes require mobility of the components, the organic photo-polymer mixtures typically have modes overall RI values and the local variation in local RI is modest, usually well below <0.1.

In addition, organic materials and polymers usually have large coefficients of thermal expansion (CTE) as compared to inorganic substrates that the photopolymer is deposited onto. This CTE mismatch may introduce thermomechanical integration issues that often lead to interfacial failure or deformation of multi-layer components; ultimately resulting in failure of reliability and stress testing for the overall optical device.

Overall, the mechanistic and materials limitations in organic photopolymers mean that they are not compatible with latent chemistry phot-patterning and the base RI and RI modulation values cannot be increased significantly above >1.6 and >0.1, respectively, without decreasing optical performance and image quality.

Photo-thermo-refractive (PTR) glasses are an inorganic alternative to photopolymer that also relies on the displacement and aggregation of formulation components to generate variations in RI as shown in FIG. 13B. In this case, the material is typically a silicate glass containing RI contrast elements, such as Na⁺ and F⁻, and doped with photo-reactive species, such as Ag⁺ and Ce⁺³. Local photo-excitation may lead to the formation of a pattern of latent chemistry, by creating Ag nanoclusters that serve as nucleation sites for the RI contrast species upon subsequent thermal annealing. Most commonly, heating at >300° C. leads to segregation of NaF around the photo-generated nanoclusters. Since NaF has a lower RI (1.32) than silicate glasses (˜1.45-1.55), the segregation results in a pattern of local RI variations.

While the mechanical and optical stability of the glass is superior to the photo-polymer examples, the need to diffuse the RI contrast components through the denser glass may limit optical properties. For example, the high annealing temperatures mean that the rate of component segregation is in competition with the rate of homogeneous mixing of the overall material. Thus, as the formation of the RI variation pattern is in direct competition with a process that erases the RI pattern and homogenizes optical properties.

In addition, since the growth rate of NaF is higher than the nucleation rate, the increase in RI contrast can occur at the expense of domain formation and potential haze from the domains growing too large.

Overall, while PTR glasses have a distinct latent chemistry photo-patterning mechanism, they have relatively low base RI values and they may not be able to produce VBG or holographic patterns with RI variations above 0.001.

Sol-gel coatings have been used as an alternative inorganic materials class with improved diffusion and reorganization potential. Sol-gels comprise coatings containing metal oxide precursors that progressively condense upon heating by eliminating solvent and organic ligands to finally form a glassy state. The condensation process is accompanied by a significant reorganization of film microstructure and shrinkage, thus improved diffusion needs to be leveraged against local thickness variations and patterned feature deformation.

Sol-gels coatings may be used to generation of VBG and holographic patterns by incorporating a photo-polymerizable organic ligand that enables a photo-induced segregation behavior similar to that of photopolymers as shown in FIG. 13C. Thus, sol-gel examples in the literature may have similar limitations to photopolymers in terms of limited RI variation, scattering and pattern integrity issues related to the fact that there is no latent chemistry mechanism. Indeed, the photo-induced RI variations demonstrated in these films is <0.1, even though the base RI of the organic components can be much higher than that of organic photo-polymer materials.

In addition, the increased coating shrinkage observed when sol-gels are annealed means that the final local thickness variation issues are pronounced. The thickness variation may lead to the formation of a secondary surface indentation pattern above the photo-induced pattern within the film. This indentation pattern can also act to diffract and refract light, thus lowering the image quality produced by the photo-recorded pattern.

Thus, while sol-gel can provide improved diffusion over PTR glasses and increased base RI versus organic-photopolymers, the fact that their photo-patterning still relies on diffusion and segregation means that local RI variation is still <0.1.

VBG and holographic patterns can also be recorded onto gelatin layers sensitized with dichromate or silver halide as shown in FIG. 13D. In the first case, photo-induced reduction of Cr^{VI} centers within a hydrated gelatin coating can be used to control local cross-linking of the gelatin scaffold. Through a series of aging and wet post-processing steps, the unreacted Cr^{VI} is removed, and the partially reduced Cr in the photo-exposed areas is fully reduced to Cr^{III}. Once the gelatin is dried, the areas that contain Cr^{III} will show higher densification, while the unexposed areas might be denser or even show micro-voids; thereby creating a pattern of local

RI variations within the gelatin layer.

The silver halide process operates through a related mechanism as shown in FIG. 13D, wherein Ag⁺ is the photosensitizer that oxidizes the gelatin upon light exposure. Upon removal of soluble Ag⁺ in the non-exposed areas, the Ag clusters are bleached and replaced by Cr^{III}, which similarly helps to increase the local density of the gelatin.

While both variations of this approach allow for recording via latent chemistry onto gelatin layers with high transmission and low scattering, they still suffer from the optical and reliability challenges of organic materials. For example, the base RI of gelatin is moderate (e.g., about 1.54) and RI variation is usually below about 0.1. In the case of Ag halide, scattering of the Ag emulsion and the photo-exposed product can also introduce image quality issues. In addition, the hygroscopic nature of the gelatin scaffold may require complete encapsulation of the layer to prevent variations in RI or complete erasing of the photo-generated pattern. Thus, application of this type of material in consumer products, such as waveguides for wearable electronic displays, is limited.

SnO(x)Cl(y) coatings can be formed using a non-hydrolytic sol-gel approach, wherein the Sn valence and O vs. Cl ratio can be controlled by the sol-gel solvent choice. The coatings can have constant RI values that range from about 1.60 to about 2.10. The same SnO(x)Cl(y) material class could be used to create coatings with variable RI values. The local RI control results from gradual changes in solvent type and content in the coating prior to annealing. For example, by increasing the content of isopropanol solvent in portions of the coating, the RI can be reduced to about 1.6, whereas other portions enriched with DPGME solvent may show RI values as high as about 2.1. The local solvent variations can be achieved via selective deposition techniques such as ink-jet printing. Furthermore, since the final coatings are primarily made up of inorganic components, their environmental stability, reliability, and integration compatibility with inorganic substrate are more promising than organic counterparts.

While this material class appears to strongly respond to slight changes in its chemical environment by shifting its post-anneal composition and RI, those changes in the chemical environment cannot be induced via photo-excitation. It is thus necessary to develop new materials and process that allow for recording patterns of RI variations using light, with the material's base RI greater than about 1.6 and RI modulation >0.1.

Hwang et al. (Electrochemical and Solid-State Letters, 15 (4) H91-H93 (2012), DOI 10.1149/2.013204esl) shows that a Zinc-Tin Oxide coating made from a solution of SnCl2, Zn(AcO)2, Acetylacetonate and alcohol solvent can be annealed to SnO2, and that photo-excitation of the film prior to annealing can accelerate the condensation process. This example showed no photo-patterning ability, the excitation wavelength was deep in the UV range, the anneal temperatures were too high for compatibility with other common temperature-sensitive coating used in WGs, the photoexcitation times were too prolonged for high-fidelity recording of WG features, and the deposit thickness was <25 nm.

Sanctis et al. (Adv. Mater. Interfaces 2018, 1800324, DOI: 10.1002/admi.201800324) similarly shows that an Indium/Zinc-Tin Oxide pattern can be photo-generated via photo-condensation of metal-Schiff base complex into insoluble deposits. After washing away the material from non-exposed areas and annealing the deposits, mixed photo-patterned features of mixed tin (IV) oxides are obtained. In this example, there is no local RI variation (since the material is fully removed from non-exposed areas), the deposit thickness is less than about 25 nm, and excitation times are too long and anneal temperatures too high for application in the manufacturing of WG devices.

According to certain embodiments, a sol-gel material for recording holographic optical elements (e.g., volume Bragg gratings) may include a (precursor) solution containing a tin dichloride salt, at least one alcohol-containing solvent, and optionally a photo-acid generator or photo-acid. The sol-gel material may be used to form a continuous coating characterized by a formula SnO(n)X(m) as a result of selective photo-excitation followed by blanket thermal annealing, where the n-m ratio and n-m values may vary across regions of the coating, such that the local RI of the coating is actively varied without affecting the coating's transparency.

In some embodiments, the tin dichloride salt may include anhydrous tin dichloride, tin dichloride hydrate, or tin (II) ions and chloride ions provided to the solution from separate salts. The solvent may contain at least one alcohol, such as an alkyl alcohol, a glycol, or a diol. The solvent may be a solvent mixture that may include at least one of dipropylene Glycol Monomethyl Ether (DPGME), propylene Glycol Monomethyl Ether (PGME), ethanol, isopropanol, propanol, 1,3-Dimethoxy-2-propanol, and diethylene glycol, propylene glycol methyl ether acetate, tripropylene glycol monomethyl ether, butyl lactate, propylene carbonate, methanol, or water. The coating solution may optionally include a photo-acid generator or photo-acid. The photo-acid generator or photo-acid may include at least one of a diarylsulfonium compound, a diazomethane compound, a bis (sulfonyl) diazomethane compound, a Diaryliodonium compound, a triarylselenonium compound, an arene ferrocene compound, or a sulfonic acid ester compound.

In some embodiments, a coating may be prepared from the sol-gel precursor solution to form a layer composed of SnO(n)X(m). The coating, once thermally annealed and optionally photo-cured, may have an RI between about 1.65 and about 2.35, where all portions of the coating may show absorption values less than 0.1% in the visible spectrum. In some embodiments, a coating composed of SnO(n)X(m) with variable n-m values and n:m ratio may be resulted from selective photo-curing of the coating prior to completing the thermal annealing process, such that local RI values may vary from about 1.65 to about 2.35 and all portions of the film may show absorption values less than about 0.1% in the visible spectrum. In some embodiments, a coating may include photo-exposed regions having RI values that are lower than those of the non-photo-exposed regions, and the photo-exposed regions may have an n value of about 1.5-2 and an men ratio greater than about 3. In some embodiments, the m-n values, men ratio, and resultant local RI values of a coating disclosed herein may be controlled by the intensity, exposure time, and wavelength of photo-excitation followed by thermal annealing.

In some embodiments, a process may include applying the sol-gel precursor solution disclosed herein onto a substrate via spin-coating, ink-jet printing, dip-coating, spray-coating, screen-printing, contact-printing, or casting, to form a coating layer. In some embodiments, a portion of the coating layer may be cured using a light source with an excitation wavelength longer than 365 nm and excitation power no more than about 300 mW/cm² for about 0.001 to about 300 seconds, such that the photo-exposed areas may have a lower RI value than the non-exposed areas after thermal annealing. In some embodiments, a portion of the coating layer may be photo-cured using a light pattern formed by constructive and destructive interference to create a (latent) holographic optical element (e.g., VBG) within the coating following thermal annealing. The substrate with the photo-cured coating layer may be thermally annealed via at least 1 stage of thermal annealing after photo-excitation, at annealing temperatures lower than about 300° C., or may optionally be thermally annealed via at least 2 stages of annealing, where the initial anneal may occur before or after the photo-excitation step, the temperature of the first anneal step is lower than about 200° C., and the temperature of the final anneal step is lower than about 300° C. After the thermal annealing, a transparent coating with local variations in RI may be formed, where the local RI may vary by at least about 0.1 (refractive index modulation) and the overall RI may vary in the range of about 1.65-2.35.

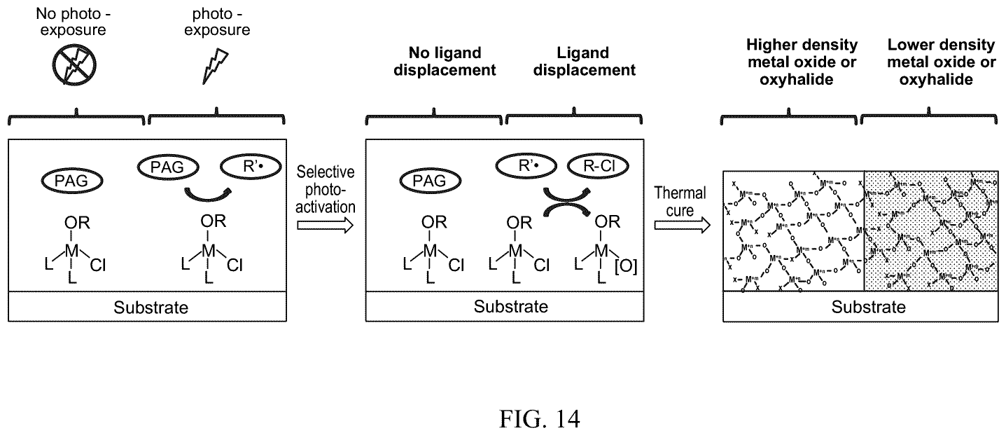

FIG. 14 illustrates an example of displacing labile ligand in sol-gel coating with photo-generated base to form latent chemistry for refractive index modulation. In some embodiments, sol-gel material for optical coating may be a solution containing a tin dichloride salt, at least one alcohol-containing solvent, and optionally a photo-acid generator or photo-acid. The sol-gel material may form a continuous coating composed of SnO(n)X(m), whose n-m ratio and n-m values can be varied across the length of the coating dimensions as a result of selective photo-excitation followed by blanket thermal annealing, such that the local RI of the coating is varied without affecting the coating's transparency.

In some embodiments, the tin dichloride salt may be anhydrous tin dichloride, tin dichloride hydrate. In some cases, tin (II) ions and chloride ions are provided from the separate salts. The solvent may contain at least one alcohol, such as an alkyl alcohol, a glycol, or a diol. The solvent may be a solvent mixture that may include at least one of dipropylene glycol monomethyl ether (DPGME), propylene glycol monomethyl ether (PGME), ethanol, isopropanol, propanol, 1,3-dimethyl-2-propanol, diethylene glycol, propylene glycol methyl ether acetate, tripropylene glycol monomethyl ether, butyl lactate, propylene carbonate, methanol, or water. The coating solution may optionally include a photo-acid generator or photoacid. The photo-acid generator or photo-acid for the precursor solution may include at least one of a diarylsulfonium compound, a diazomethane compound, a bis (sulfonyl) diazomethane compound, a diaryliodonium compound, triarylselenonium compound, an arene ferrocene compound, or a sulfonic acid ester compound.

In some embodiments, a coating may be prepared from the precursor solution to form a layer containing SnO(n)X(m). The coating, once thermally annealed and optionally photo-cured, may have a RI value between about 1.65 and about 2.35 and all portions of the film show absorption values <0.1% in the visible spectrum. In some embodiments, a coating composed of SnO(n)X(m) with variable n-m values and n:m ratio may be resulting from selective photo-curing of the coating prior to completing the thermal annealing process, such that local RI values may vary from 1.65 to 2.35 and all portions of the film may show absorption values <0.1% in the visible spectrum. In some embodiments, a coating may include photo-exposed regions having RI values that are lower than those of the non-photo-exposed regions, and the photo-exposed regions may have an n value of 1.5-2 and an men ratio >3. In some embodiments, the m-n values, m:n ratio, and resultant local RI values of a coating disclosed herein may be controlled by the intensity, exposure time, and wavelength of photo-excitation followed by thermal annealing.

In some embodiments, a process for applying the sol-gel precursor solution disclosed herein onto the substrate may include spin-coating, ink-jet printing, dip-coating, spray-coating, screen-printing, contact-printing, or casting. In some embodiments, a portion of the coating layer may be cured using a light source with an excitation wavelength >365 nm and power of ≤300 mW/cm² for 0.001 to 300 seconds, such that the photo-exposed areas may have a lower RI value than the non-exposed areas after thermal annealing. In some embodiments, a portion of the coating layer may be photo-cured using a light pattern formed by constructive and destructive interference to create a (latent) holographic optical element (e.g., VBG) within the coating, followed by thermal annealing. The substrate with the photo-cured coating layer may be thermally annealed via at least 1 stage of thermal annealing after photo-excitation, at annealing temperatures <300° C., or may optionally be thermally annealed via at least 2 stages of annealing, where the initial anneal may occur before or after the photo-excitation step, the temperature of the first anneal step is <200° C., and the temperature of the final anneal step is <300° C. After the thermal annealing, a transparent coating with local variations in RI may be formed, where the local RI may vary by at least 0.01 (refractive index modulation) and the overall RI may vary in the range of 1.65-2.35.

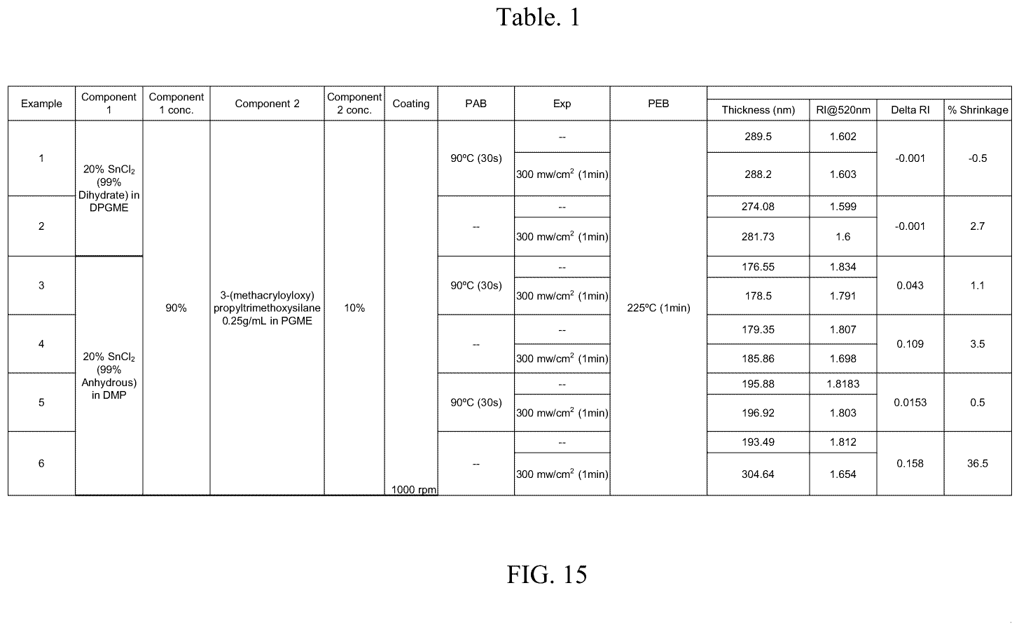

FIGS. 15-23 illustrate examples of experimental results using comparative materials

and processes, and materials and processes disclosed herein according to certain embodiments. FIG. 15 includes Table 1 illustrating examples of experimental results using comparative materials and processes. Table 1 shows the RI and thickness of the coatings measured via ellipsometry and the change in RI and thickness accompanying selective photo-curing for comparative examples 1-6. In the examples, different solutions containing a tin (II) dichloride salt and 3-(methylacryloyloxy) propyltrimethoxysilane, a photo-segregation agent, were prepared. The photo-segregation agent contains a photo-polymerizable methacrylate unit which may condense locally within the film upon photo-exposure. The addition of photo-segregation agent serves as a good counterpart to the existing photo-polymer material systems, as well as a comparison to other photo-reactive sol-gel examples. The solutions were then deposited then deposited onto a substrate via spin-coating at different speeds (to control deposit thickness) and optionally processed via a first anneal consisting of heating at 90° C. for 30 seconds. The introduction of this anneal step changes the potential mobility and reactivity of coating components based on the partial removal of solvent and partial condensation of inorganic components. Each sample was then partially exposed to photo-excitation and each sample was annealed at 225° C. for about 1 minute, resulting in a permanent coating.

Examples 1-6 illustrated in Table 1 of FIG. 15 show that choice of solvent and tin dichloride salt influence photo-reactivity and RI of the coating prior to photo-exposure. In cases where the coating was annealed prior to the photo-excitation, the effect of selective photo-exposure may be minimal. In cases where the photo-exposure is applied without thermal annealing exhibited a moderate change in RI of 0.158. The difference in thickness between exposed and non-exposed regions may also vary, depending on the specific solution component and post-coating processing exploited. These examples show that photo-segregation approach may be used to induce a moderate change in local RI values, when some solvent is present in the film.

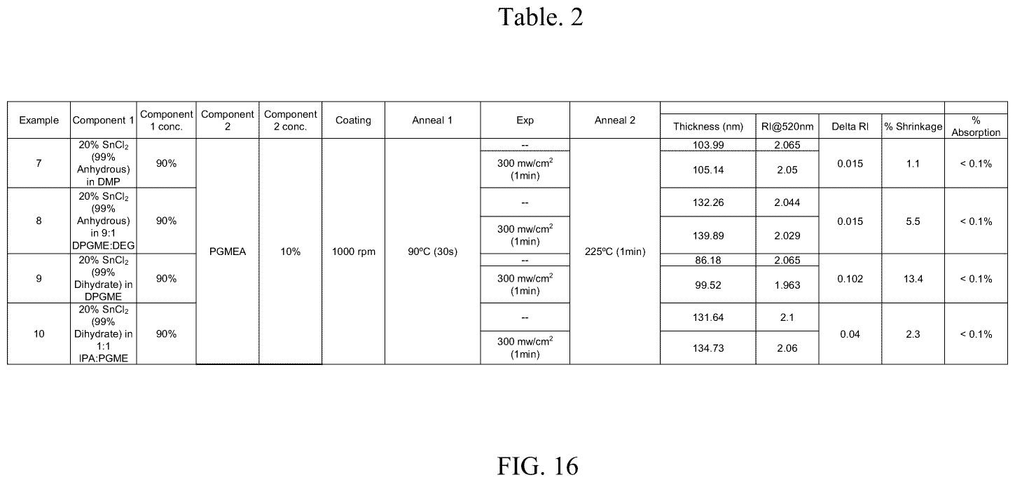

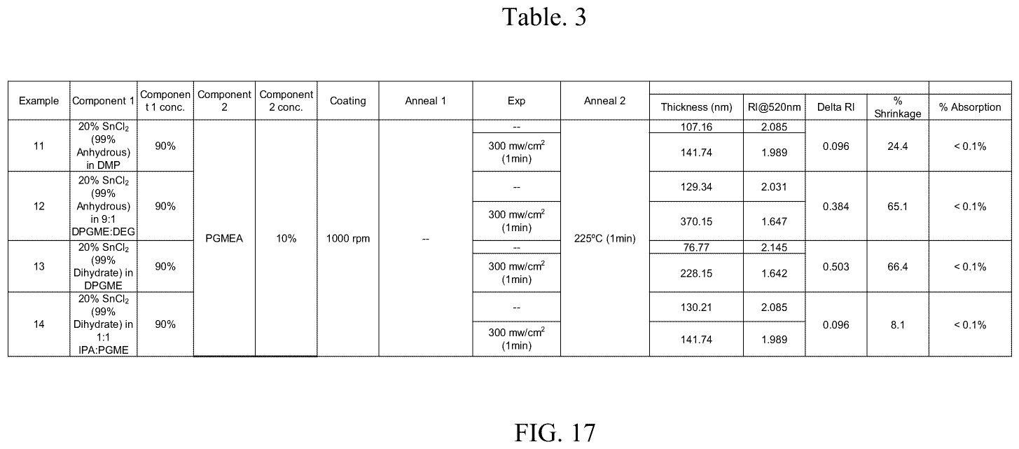

Table 2 in FIG. 16 and Table 3 in FIG. 17 summarize experimental results for examples 7-14, where experimental protocols similar to the experimental protocols used for examples 1-6 were used for solutions containing solvents and different tin (II) dichloride salts. These examples show that there is photo-reactivity within the mixture of Sn (II) dichloride and alcohol-containing solvents. Compared to the examples 1-6, the change in RI is higher in examples 7-14 whether or not the coating is annealed prior to selective photo-curing. Large changes in reactivity may be observed depending on the type of tin dichloride salt and or the type of solvent. Direct photo-excitation of the tin mixture provided an RI change as high as 0.5 at the expense of larger changes in final coating thickness between exposed and unexposed areas. The highest RI for a non-exposed region in these examples is 2.15. This is larger than those achieved in examples 1-6. There is no significant difference in RI between photo-exposed and non-photo-exposed areas prior to the final anneal, suggesting that this photo-patterning technique relies on creating a pattern of latent chemistry that comes through as a sharp change in optical properties during post-processing. All examples, regardless of curing protocol, are highly transparent with absorption values across the visible spectrum <0.1%.

These examples show that direct photo-excitation of the Sn-alcohol solvent system provides broader range of base RI and RI changes compared to the diffusion and segregation-based mechanism. The fact that all un-exposed areas in these examples show higher RI than exposed areas suggest that photo-excitation cases the direct transition to a phase richer in Sn(IV)O₂. That is, photo-excitation leads to higher m values and higher min ratios in the SnO(m)Cl(n) system. Without being bound by theory, these results suggest that photo-excitation enables the chemical environment around the Sn center to be more readily oxidized, or enables any of the surrounding moieties to readily act as an oxo-ligand donor. Thus, the mechanism disclosed herein for controlling the local RI in sol-gel relies on the photo-induced latent chemistry pattern.

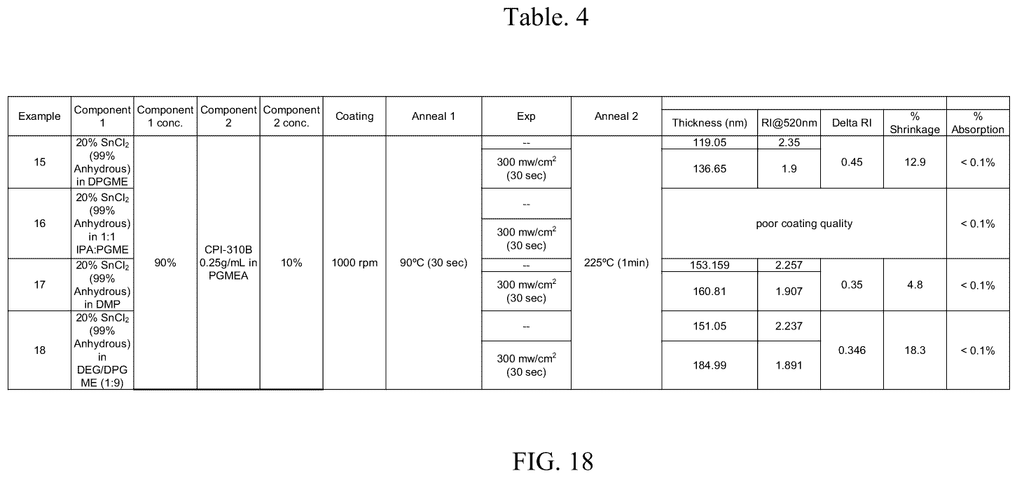

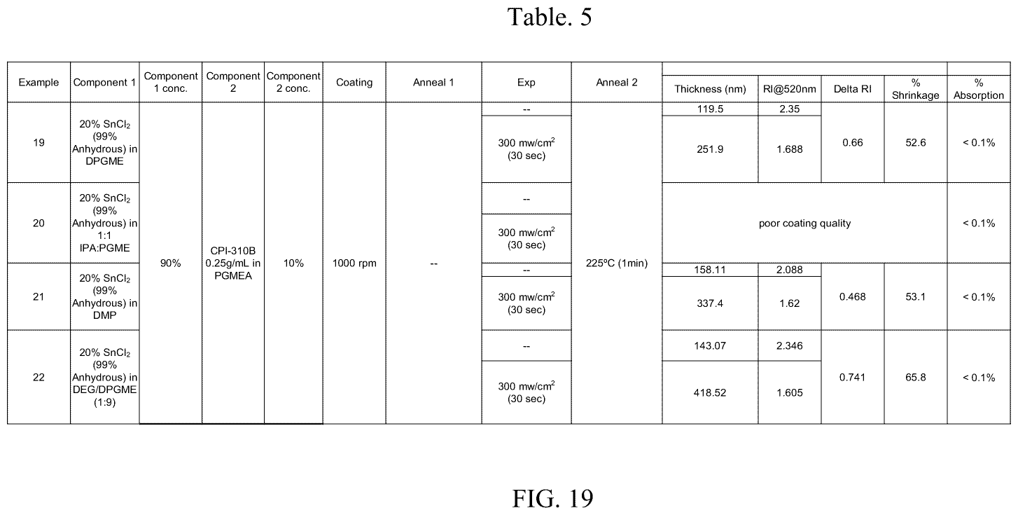

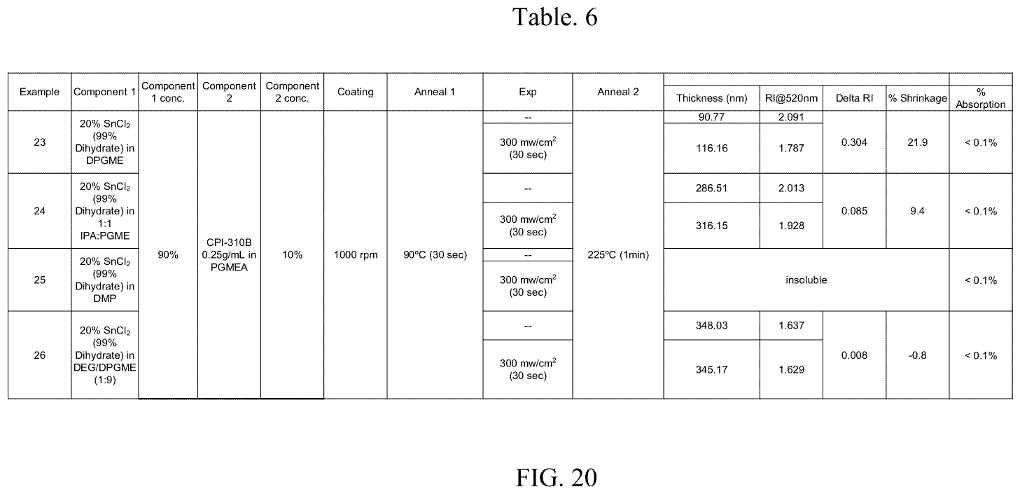

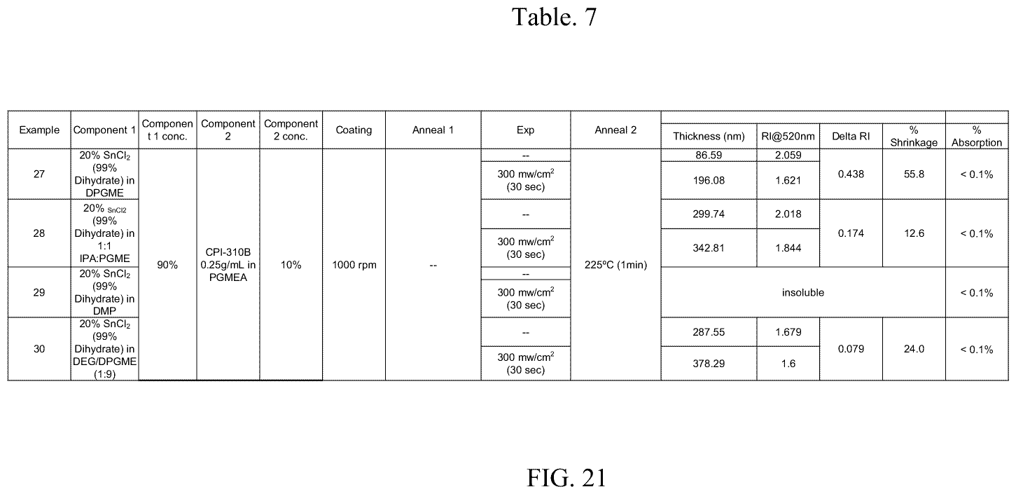

Table 4 in FIG. 18, Table 5 in FIG. 19, Table 6 in FIG. 20, and Table 7 in FIG. 21 summarize experimental results for the examples 15-30, where experimental protocols similar to the experimental protocols used for examples 1-6 were used for solutions containing solvents and different tin (II) dichloride salts and a photo-acid generator (PAG). These examples shows that the photo-reactivity in examples 7-14 can be further enhanced due to the photo-reactivity of the PAG. In the examples, change in RI values between exposed and non-exposed are increased to 0.74, while decreasing the thickness difference between the exposed and non-exposed areas to <5% with change in RI values >0.3. Notably, variation in RI as high as 0.45 was achieved even when the sample was annealed prior to selective photo-exposure. This suggest that the photo-patterning mechanism may be exploited even in a partially dried environment where diffusion and mobility is drastically reduced. This is different from other latent-chemistry photo-patterning approaches, where the latent-chemistry may still involve long-range re-organization of the components to create a change in local RI (for example, as PTR glass in FIG. 13B). Thus, the approach described herein can maximize changes in photo-induced optical properties without relying on high mobility states that can complicate the manufacturing of optical elements such as waveguides.

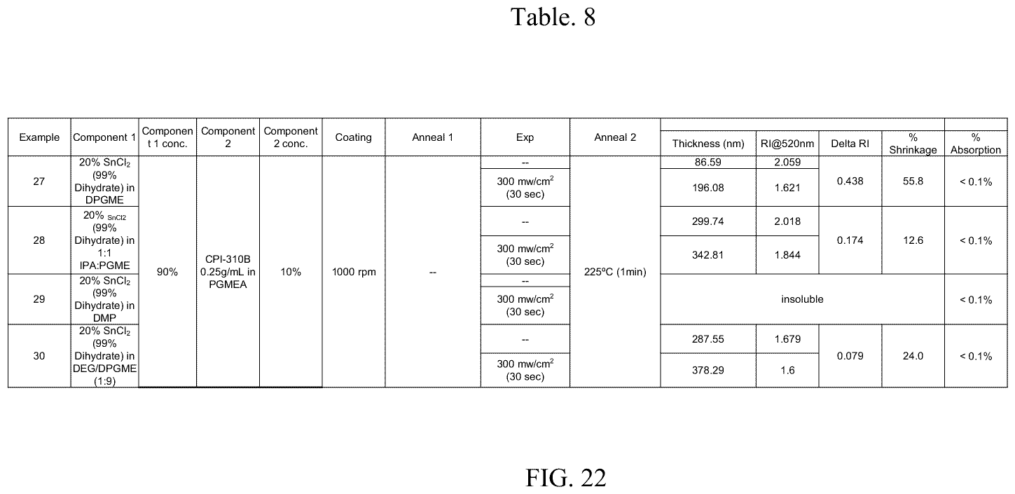

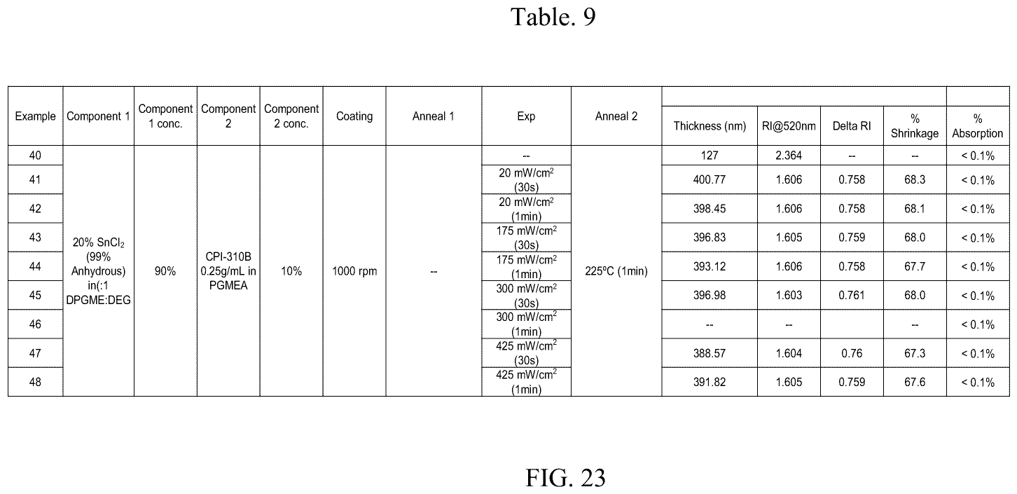

Table 8 in FIG. 22 and Table 9 in FIG. 23 summarize experimental results for examples 31-48, where the experiments corresponding to examples 18 and 22 were repeated at varying intensities and duration of the photo-exposure step. The examples show that the difference in thickness and RI between non-exposed and photo-exposed areas varied depending on these conditions. The variation observed in these examples suggests that the pattern of latent chemistry changes depends on the specific balance achieved between Sn-alcohol and PAG photo-chemistries. These can result in different optical and shrinking patterns during the thermal post-processing. Moreover, these examples show that the selective photo-excitation process can be tuned to select a desired change in optical properties; and that it is achievable to create a pattern with large changes in RI (e.g., 0.75) even with the photo-excitation power as low as 20 mW/cm².

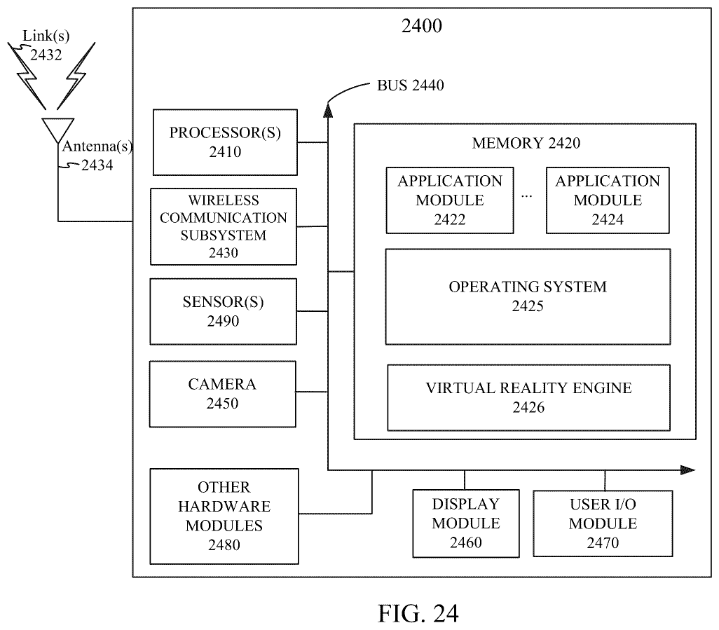

FIG. 24 is a simplified block diagram of an example of an electronic system 2400 of a near-eye display system (e.g., HMD device) for implementing some of the examples disclosed herein. Electronic system 2400 may be used as the electronic system of an HMD device or other near-eye displays described above. In this example, electronic system 2400 may include one or more processor(s) 2410 and a memory 2420. Processor(s) 2410 may be configured to execute instructions for performing operations at a number of components, and can be, for example, a general-purpose processor or microprocessor suitable for implementation within a portable electronic device. Processor(s) 2410 may be communicatively coupled with a plurality of components within electronic system 2400. To realize this communicative coupling, processor(s) 2410 may communicate with the other illustrated components across a bus 2440. Bus 2440 may be any subsystem adapted to transfer data within electronic system 2400. Bus 2440 may include a plurality of computer buses and additional circuitry to transfer data.

Memory 2420 may be coupled to processor(s) 2410. In some embodiments, memory 2420 may offer both short-term and long-term storage and may be divided into several units. Memory 2420 may be volatile, such as static random access memory (SRAM) and/or dynamic random access memory (DRAM) and/or non-volatile, such as read-only memory (ROM), flash memory, and the like. Furthermore, memory 2420 may include removable storage devices, such as secure digital (SD) cards. Memory 2420 may provide storage of computer-readable instructions, data structures, program modules, and other data for electronic system 2400. In some embodiments, memory 2420 may be distributed into different hardware modules. A set of instructions and/or code might be stored on memory 2420. The instructions might take the form of executable code that may be executable by electronic system 2400, and/or might take the form of source and/or installable code, which, upon compilation and/or installation on electronic system 2400 (e.g., using any of a variety of generally available compilers, installation programs, compression/decompression utilities, etc.), may take the form of executable code.

In some embodiments, memory 2420 may store a plurality of application modules 2422 through 2424, which may include any number of applications. Examples of applications may include gaming applications, conferencing applications, video playback applications, or other suitable applications. The applications may include a depth sensing function or eye tracking function. Application modules 2422-2424 may include particular instructions to be executed by processor(s) 2410. In some embodiments, certain applications or parts of application modules 2422-2424 may be executable by other hardware modules 2480. In certain embodiments, memory 2420 may additionally include secure memory, which may include additional security controls to prevent copying or other unauthorized access to secure information.

In some embodiments, memory 2420 may include an operating system 2425 loaded therein. Operating system 2425 may be operable to initiate the execution of the instructions provided by application modules 2422-2424 and/or manage other hardware modules 2480 as well as interfaces with a wireless communication subsystem 2430 which may include one or more wireless transceivers. Operating system 2425 may be adapted to perform other operations across the components of electronic system 2400 including threading, resource management, data storage control and other similar functionality.

Wireless communication subsystem 2430 may include, for example, an infrared communication device, a wireless communication device and/or chipset (such as a Bluetooth® device, an IEEE 802.11 device, a Wi-Fi device, a WiMax device, cellular communication facilities, etc.), and/or similar communication interfaces. Electronic system 2400 may include one or more antennas 2434 for wireless communication as part of wireless communication subsystem 2430 or as a separate component coupled to any portion of the system. Depending on desired functionality, wireless communication subsystem 2430 may include separate transceivers to communicate with base transceiver stations and other wireless devices and access points, which may include communicating with different data networks and/or network types, such as wireless wide-area networks (WWANs), wireless local area networks (WLANs), or wireless personal area networks (WPANs). A WWAN may be, for example, a WiMax (IEEE 802.16) network. A WLAN may be, for example, an IEEE 802.11x network. A WPAN may be, for example, a Bluetooth network, an IEEE 802.15x, or some other types of network. The techniques described herein may also be used for any combination of WWAN, WLAN, and/or WPAN. Wireless communications subsystem 2430 may permit data to be exchanged with a network, other computer systems, and/or any other devices described herein. Wireless communication subsystem 2430 may include a means for transmitting or receiving data, such as identifiers of HMD devices, position data, a geographic map, a heat map, photos, or videos, using antenna(s) 2434 and wireless link(s) 2432. Wireless communication subsystem 2430, processor(s) 2410, and memory 2420 may together comprise at least a part of one or more of a means for performing some functions disclosed herein.

Embodiments of electronic system 2400 may also include one or more sensors 2490. Sensor(s) 2490 may include, for example, an image sensor, an accelerometer, a pressure sensor, a temperature sensor, a proximity sensor, a magnetometer, a gyroscope, an inertial sensor (e.g., a module that combines an accelerometer and a gyroscope), an ambient light sensor, or any other similar module operable to provide sensory output and/or receive sensory input, such as a depth sensor or a position sensor. For example, in some implementations, sensor(s) 2490 may include one or more inertial measurement units (IMUs) and/or one or more position sensors. An IMU may generate calibration data indicating an estimated position of the HMD device relative to an initial position of the HMD device, based on measurement signals received from one or more of the position sensors. A position sensor may generate one or more measurement signals in response to motion of the HMD device. Examples of the position sensors may include, but are not limited to, one or more accelerometers, one or more gyroscopes, one or more magnetometers, another suitable type of sensor that detects motion, a type of sensor used for error correction of the IMU, or some combination thereof. The position sensors may be located external to the IMU, internal to the IMU, or some combination thereof. At least some sensors may use a structured light pattern for sensing.

Electronic system 2400 may include a display module 2460. Display module 2460 may be a near-eye display, and may graphically present information, such as images, videos, and various instructions, from electronic system 2400 to a user. Such information may be derived from one or more application modules 2422-2424, virtual reality engine 2426, one or more other hardware modules 2480, a combination thereof, or any other suitable means for resolving graphical content for the user (e.g., by operating system 2425). Display module 2460 may use liquid crystal display (LCD) technology, light-emitting diode (LED) technology (including, for example, OLED, ILED, μLED, AMOLED, TOLED, etc.), light emitting polymer display (LPD) technology, or some other display technology.

Electronic system 2400 may include a user input/output module 2470. User input/output module 2470 may allow a user to send action requests to electronic system 2400. An action request may be a request to perform a particular action. For example, an action request may be to start or end an application or to perform a particular action within the application. User input/output module 2470 may include one or more input devices. Example input devices may include a touchscreen, a touch pad, microphone(s), button(s), dial(s), switch(es), a keyboard, a mouse, a game controller, or any other suitable device for receiving action requests and communicating the received action requests to electronic system 2400. In some embodiments, user input/output module 2470 may provide haptic feedback to the user in accordance with instructions received from electronic system 2400. For example, the haptic feedback may be provided when an action request is received or has been performed.

Electronic system 2400 may include a camera 2450 that may be used to take photos or videos of a user, for example, for tracking the user's eye position. Camera 2450 may also be used to take photos or videos of the environment, for example, for VR, AR, or MR applications. Camera 2450 may include, for example, a complementary metal-oxide-semiconductor (CMOS) image sensor with a few millions or tens of millions of pixels. In some implementations, camera 2450 may include two or more cameras that may be used to capture 3-D images.

In some embodiments, electronic system 2400 may include a plurality of other hardware modules 2480. Each of other hardware modules 2480 may be a physical module within electronic system 2400. While each of other hardware modules 2480 may be permanently configured as a structure, some of other hardware modules 2480 may be temporarily configured to perform specific functions or temporarily activated. Examples of other hardware modules 2480 may include, for example, an audio output and/or input module (e.g., a microphone or speaker), a near field communication (NFC) module, a rechargeable battery, a battery management system, a wired/wireless battery charging system, etc. In some embodiments, one or more functions of other hardware modules 2480 may be implemented in software.

In some embodiments, memory 2420 of electronic system 2400 may also store a virtual reality engine 2426. Virtual reality engine 2426 may execute applications within electronic system 2400 and receive position information, acceleration information, velocity information, predicted future positions, or some combination thereof of the HMD device from the various sensors. In some embodiments, the information received by virtual reality engine 2426 may be used for producing a signal (e.g., display instructions) to display module 2460. For example, if the received information indicates that the user has looked to the left, virtual reality engine 2426 may generate content for the HMD device that mirrors the user's movement in a virtual environment. Additionally, virtual reality engine 2426 may perform an action within an application in response to an action request received from user input/output module 2470 and provide feedback to the user. The provided feedback may be visual, audible, or haptic feedback. In some implementations, processor(s) 2410 may include one or more GPUs that may execute virtual reality engine 2426.

In various implementations, the above-described hardware and modules may be implemented on a single device or on multiple devices that can communicate with one another using wired or wireless connections. For example, in some implementations, some components or modules, such as GPUs, virtual reality engine 2426, and applications (e.g., tracking application), may be implemented on a console separate from the head-mounted display device. In some implementations, one console may be connected to or support more than one HMD.

In alternative configurations, different and/or additional components may be included in electronic system 2400. Similarly, functionality of one or more of the components can be distributed among the components in a manner different from the manner described above. For example, in some embodiments, electronic system 2400 may be modified to include other system environments, such as an AR system environment and/or an MR environment.

The methods, systems, and devices discussed above are examples. Various embodiments may omit, substitute, or add various procedures or components as appropriate. For instance, in alternative configurations, the methods described may be performed in an order different from that described, and/or various stages may be added, omitted, and/or combined. Also, features described with respect to certain embodiments may be combined in various other embodiments. Different aspects and elements of the embodiments may be combined in a similar manner. Also, technology evolves and, thus, many of the elements are examples that do not limit the scope of the disclosure to those specific examples.

Specific details are given in the description to provide a thorough understanding of the embodiments. However, embodiments may be practiced without these specific details. For example, well-known circuits, processes, systems, structures, and techniques have been shown without unnecessary detail in order to avoid obscuring the embodiments. This description provides example embodiments only, and is not intended to limit the scope, applicability, or configuration of the invention. Rather, the preceding description of the embodiments will provide those skilled in the art with an enabling description for implementing various embodiments. Various changes may be made in the function and arrangement of elements without departing from the spirit and scope of the present disclosure.

Also, some embodiments were described as processes depicted as flow diagrams or block diagrams. Although each may describe the operations as a sequential process, many of the operations may be performed in parallel or concurrently. In addition, the order of the operations may be rearranged. A process may have additional steps not included in the figure. Furthermore, embodiments of the methods may be implemented by hardware, software, firmware, middleware, microcode, hardware description languages, or any combination thereof. When implemented in software, firmware, middleware, or microcode, the program code or code segments to perform the associated tasks may be stored in a computer-readable medium such as a storage medium. Processors may perform the associated tasks.

It will be apparent to those skilled in the art that substantial variations may be made in accordance with specific requirements. For example, customized or special-purpose hardware might also be used, and/or particular elements might be implemented in hardware, software (including portable software, such as applets, etc.), or both. Further, connection to other computing devices such as network input/output devices may be employed.

With reference to the appended figures, components that can include memory can include non-transitory machine-readable media. The term “machine-readable medium” and “computer-readable medium” may refer to any storage medium that participates in providing data that causes a machine to operate in a specific fashion. In embodiments provided hereinabove, various machine-readable media might be involved in providing instructions/code to processing units and/or other device(s) for execution. Additionally or alternatively, the machine-readable media might be used to store and/or carry such instructions/code. In many implementations, a computer-readable medium is a physical and/or tangible storage medium.

Such a medium may take many forms, including, but not limited to, non-volatile media, volatile media, and transmission media. Common forms of computer-readable media include, for example, magnetic and/or optical media such as compact disk (CD) or digital versatile disk (DVD), punch cards, paper tape, any other physical medium with patterns of holes, a RAM, a programmable read-only memory (PROM), an erasable programmable read-only memory (EPROM), a FLASH-EPROM, any other memory chip or cartridge, a carrier wave as described hereinafter, or any other medium from which a computer can read instructions and/or code. A computer program product may include code and/or machine-executable instructions that may represent a procedure, a function, a subprogram, a program, a routine, an application (App), a subroutine, a module, a software package, a class, or any combination of instructions, data structures, or program statements.

Those of skill in the art will appreciate that information and signals used to communicate the messages described herein may be represented using any of a variety of different technologies and techniques. For example, data, instructions, commands, information, signals, bits, symbols, and chips that may be referenced throughout the above description may be represented by voltages, currents, electromagnetic waves, magnetic fields or particles, optical fields or particles, or any combination thereof.

Terms, “and” and “or” as used herein, may include a variety of meanings that are also expected to depend at least in part upon the context in which such terms are used. Typically, “or” if used to associate a list, such as A, B, or C, is intended to mean A, B, and C, here used in the inclusive sense, as well as A, B, or C, here used in the exclusive sense. In addition, the term “one or more” as used herein may be used to describe any feature, structure, or characteristic in the singular or may be used to describe some combination of features, structures, or characteristics. However, it should be noted that this is merely an illustrative example and claimed subject matter is not limited to this example. Furthermore, the term “at least one of” if used to associate a list, such as A, B, or C, can be interpreted to mean A, B, C, or any combination of A, B, and/or C, such as AB, AC, BC, AA, ABC, AAB, AABBCCC, and the like.

Further, while certain embodiments have been described using a particular combination of hardware and software, it should be recognized that other combinations of hardware and software are also possible. Certain embodiments may be implemented only in hardware, or only in software, or using combinations thereof. In one example, software may be implemented with a computer program product containing computer program code or instructions executable by one or more processors for performing any or all of the steps, operations, or processes described in this disclosure, where the computer program may be stored on a non-transitory computer readable medium. The various processes described herein can be implemented on the same processor or different processors in any combination.

Where devices, systems, components or modules are described as being configured to perform certain operations or functions, such configuration can be accomplished, for example, by designing electronic circuits to perform the operation, by programming programmable electronic circuits (such as microprocessors) to perform the operation such as by executing computer instructions or code, or processors or cores programmed to execute code or instructions stored on a non-transitory memory medium, or any combination thereof. Processes can communicate using a variety of techniques, including, but not limited to, conventional techniques for inter-process communications, and different pairs of processes may use different techniques, or the same pair of processes may use different techniques at different times.

The specification and drawings are, accordingly, to be regarded in an illustrative rather than a restrictive sense. It will, however, be evident that additions, subtractions, deletions, and other modifications and changes may be made thereunto without departing from the broader spirit and scope as set forth in the claims. Thus, although specific embodiments have been described, these are not intended to be limiting. Various modifications and equivalents are within the scope of the following claims.

What is claimed is:

1. A sol-gel material comprising:
a solution containing a tin dichloride salt;
a solvent including at least one alcohol-containing solvent; and
optionally a photo-acid generator or photo-acid,
wherein the sol-gel material is configurable to form a coating characterized by a formula SnO(n)X(m), where n:m ratio and n-m values of the coating vary across regions of the coating as a result of selective photo-excitation followed by blanket thermal annealing, such that a refractive index of the coating varies across the regions of the coating.

2. The sol-gel material of claim 1, wherein the tin dichloride salt includes at least one of:
anhydrous tin dichloride;
tin dichloride hydrate; or
tin (II) ions and chloride ions from separate salts.

3. The sol-gel material of claim 1, wherein the solvent includes an alkyl alcohol, a glycol, a diol, or a combination thereof.

4. The sol-gel material of claim 1, wherein the solvent includes a solvent mixture comprising at least one of dipropylene Glycol Monomethyl Ether (DPGME), propylene Glycol Monomethyl Ether (PGME), ethanol, isopropanol, propanol, 1,3-Dimethoxy-2-propanol, and diethylene glycol, propylene glycol methyl ether acetate, tripropylene glycol monomethyl ether, butyl lactate, propylene carbonate, methanol, or water.

5. The sol-gel material of claim 1, wherein the photo-acid generator or photo-acid comprises at least one of a diarylsulfonium compound, a diazomethane compound, a bis (sulfonyl) diazomethane compound, a Diaryliodonium compound, a triarylselenonium compound, an arene ferrocene compound, or a sulfonic acid ester compound.

6. The sol-gel material of claim 1, wherein the coating, after the selective photo-excitation and the blanket thermal annealing, is characterized by the refractive index between 1.65 and 2.35 and absorption values in the visible spectrum less than 0.1% across the coating.

7. An optical coating layer comprising SnO(n)X(m).

8. The optical coating layer of claim 7, wherein m and n values, m:n ratio, and resultant local refractive values are controlled by intensity, exposure time, and wavelength of photo-excitation followed by thermal annealing.

9. The optical coating layer of claim 7, wherein n-m values and n:m ratio are variable and are resulted from selective photo-curing and a subsequent thermal annealing process.

10. The optical coating layer of claim 7, wherein a refractive index of the optical coating layer varies from 1.65 to 2.35, and all portions of the optical coating layer have absorption lower than 0.1% for visible light.

11. The optical coating layer of claim 7, wherein the optical coating layer includes photo-exposed regions characterized by refractive index values lower than non-photo-exposed regions, and wherein the photo-exposed regions are characterized by n values between 1.5 and 2 and an m:n ratio greater than 3.

12. The optical coating layer of claim 7, wherein the optical coating layer includes an holographic optical element formed therein.

13. A method comprising:
depositing a sol-gel material layer on a substrate via spin-coating, ink-jet printing, dip-coating, spray-coating, screen-printing, contact-printing, or casting;
exposing a portion of the sol-gel material layer to light; and
thermally annealing the substrate,
wherein, after the thermal annealing, the sol-gel material layer is characterized by a local refractive index modulation equal to or greater than about 0.1 and a refractive index varying in a range of 1.65-2.35 across regions of the sol-gel material layer.

14. The method of claim 13, wherein the sol-gel material layer comprises a sol-gel material comprising:
a solution containing a tin dichloride salt;
a solvent including at least one alcohol-containing solvent; and
optionally a photo-acid generator or photo-acid,
wherein the sol-gel material is configurable to form a coating characterized by a formula SnO(n)X(m), where nom ratio and n-m values of the coating vary across regions of the coating as a result of selective photo-excitation followed by blanket thermal annealing, such that a refractive index of the coating varies across the regions of the coating.

15. The method of claim 13, wherein exposing the portion of the sol-gel material layer to light comprises:
exposing the portion of the sol-gel material layer to a light source with an excitation wavelength >365 nm and power of ≤ 300 mW/cm² for 0.001 to 300 seconds, such that photo-4exposed areas have a lower refractive index value than non-exposed areas upon thermal annealing; or
exposing the portion of the sol-gel material layer to an interference light pattern to create a holographic optical element within the sol-gel material layer upon thermal annealing.

16. The method of claim 13, wherein thermally annealing the substrate comprises:
thermally annealing the substrate using at least one stage of thermal annealing after the exposure, at an annealing temperature lower than about 300° C.; or
thermally annealing the substrate using at least 2 stages of annealing, wherein a first annealing occurs before or after the exposure, a temperature of the first annealing is less than 200° C., and a temperature of a final annealing is less than about 300° C.
